(19) United States
(12) Patent Application Publication
(10) Pub. No.: US 2026/0089948 A1
(43) Pub. Date: Mar. 26, 2026

(54) SEMICONDUCTOR MEMORY DEVICE

(71) Applicant: Kioxia Corporation, Tokyo (JP)

(72) Inventors: Takaaki SUETSUGU, Zushi Kanagawa (JP); Shigeki KOBAYASHI, Kamakura Kanagawa (JP); Takahiro TOMIMATSU, Yokohama Kanagawa (JP)

(73) Assignee: Kioxia Corporation, Tokyo (JP)

(21) Appl. No.: 19/075,404

(22) Filed: Mar. 10, 2025

(30) Foreign Application Priority Data
Sep. 20, 2024 (JP) 2024-163293

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor memory device includes a semiconductor substrate; a memory cell array layer disposed apart from the semiconductor substrate in a first direction intersecting with the semiconductor substrate. The memory cell array layer includes: a first stacked structure and a second stacked structure arranged in a second direction; and a third stacked structure provided between the first and second stacked structures. The first to third stacked structures include a plurality of first layers and a plurality of first insulating layers alternately stacked in the first direction and extending in a third direction. The first and second stacked structures include a plurality of blocks arranged in the second direction. A plurality of blocks excluding the first block closest to the third stacked structure includes a first conductive layer in the first layer. The third stacked structure and the first block include a second insulating layer as the first layer.

### CROSS-REFERENCE TO RELATED APPLICATIONS

This application is based upon and claims the benefit of Japanese Patent Application No. 2024-163293, filed on Sep. 20, 2024, the entire contents of which are incorporated herein by reference.

### BACKGROUND

### Field

Embodiments described herein relate generally to a semiconductor memory device.

### Description of the Related Art

There has been known a semiconductor memory device including a semiconductor substrate and a memory cell array layer disposed to be opposed to this semiconductor substrate, and the memory cell array layer has a stacked structure including alternately stacked conductive layers and insulating layers and a semiconductor layer extending in a stacking direction of the conductive layers and the insulating layers and opposed to the conductive layers.

### BRIEF DESCRIPTION OF THE DRAWINGS

FIG. 1 is a schematic block diagram illustrating a configuration of a memory die MD according to a first embodiment;

FIG. 2 is a schematic circuit diagram illustrating a part of the configuration of the memory die MD;

FIG. 3 is a schematic exploded perspective view illustrating an exemplary configuration of the memory die MD;

FIG. 4 is a schematic bottom view illustrating an exemplary configuration of a chip C_{M};

FIG. 5 is a schematic plan view illustrating an exemplary configuration of a chip C_{P};

FIG. 6 is a schematic cross-sectional view illustrating a configuration of a part of the memory die MD;

FIG. 7 is a schematic cross-sectional view illustrating a configuration of a part of the memory die MD;

FIG. 8 is a schematic cross-sectional view illustrating a configuration of a part of the memory die MD;

FIG. 9 is an enlarged back view of a part of the memory block BLK in FIG. 6 viewed in the Z-direction;

FIG. 10 is an enlarged schematic cross-sectional view illustrating a part of FIG. 6;

FIG. 11 is an enlarged schematic plan view illustrating a part of the chip C_{M} indicated by D illustrated in FIG. 4;

FIG. 12 is a cross-sectional view of a part of a base layer L_{SB} of the chip C_{M} and a memory cell array layer L_{MCA} cut along the line E-E′ of FIG. 11 viewed along the arrow direction;

FIG. 13 is an enlarged schematic plan view illustrating a part indicated by F in FIG. 4;

FIG. 14 is a cross-sectional view for describing a method of manufacturing the memory die MD according to the embodiment;

FIG. 15 is a cross-sectional view for describing the method of manufacturing the memory die MD according to the embodiment;

FIG. 16 is a cross-sectional view for describing the method of manufacturing the memory die MD according to the embodiment;

FIG. 17 is a cross-sectional view for describing the method of manufacturing the memory die MD according to the embodiment;

FIG. 18 is a cross-sectional view for describing the method of manufacturing the memory die MD according to the embodiment;

FIG. 19 is a cross-sectional view for describing the method of manufacturing the memory die MD according to the embodiment;

FIG. 20 is a cross-sectional view for describing the method of manufacturing the memory die MD according to the embodiment;

FIG. 21 is a cross-sectional view for describing the method of manufacturing the memory die MD according to the embodiment;

FIG. 22 is a cross-sectional view for describing the method of manufacturing the memory die MD according to the embodiment;

FIG. 23 is a cross-sectional view for describing the method of manufacturing the memory die MD according to the embodiment;

FIG. 24 is a cross-sectional view for describing the method of manufacturing the memory die MD according to the embodiment;

FIG. 25 is a cross-sectional view for describing the method of manufacturing the memory die MD according to the embodiment;

FIG. 26 is a cross-sectional view for describing the method of manufacturing the memory die MD according to the embodiment;

FIG. 27 is an enlarged plan view of a part indicated by D of a chip C_{M} of a memory die MD according to a second embodiment;

FIG. 28 is a cross-sectional view of a part of a base layer L_{SB} of the chip C_{M} and a memory cell array layer L_{MCA} cut along the line H-H′ of FIG. 27 viewed along the arrow direction;

FIG. 29 is a cross-sectional view for describing the method of manufacturing the chip C_{M} corresponding to FIG. 28;

FIG. 30 is a plan view for describing the method of manufacturing the chip C_{M} corresponding to FIG. 27;

FIG. 31 is a cross-sectional view for describing the method of manufacturing the chip C_{M} corresponding to FIG. 28;

FIG. 32 is an enlarged plan view of a part indicated by D of a chip C_{M} of a memory die MD according to a third embodiment; and

FIG. 33 is a cross-sectional view of a part of a base layer L_{SB} of the chip C_{M} and a memory cell array layer L_{MCA} cut along the line I-I′ of FIG. 32 viewed along the arrow direction.

### DETAILED DESCRIPTION

A semiconductor memory device according to one embodiment includes a semiconductor substrate; a memory cell array layer disposed apart from the semiconductor substrate in a first direction intersecting with a surface of the semiconductor substrate. The memory cell array layer includes: a first stacked structure and a second stacked structure arranged in a second direction intersecting with the first direction; and a third stacked structure provided between the first stacked structure and the second stacked structure. Each of the first stacked structure, the second stacked structure, and the third stacked structure includes a plurality of first layers and a plurality of first insulating layers alternately stacked in the first direction and extending in a third direction intersecting with the first direction and the second direction. Each of the first stacked structure and the second stacked structure includes a plurality of blocks arranged in the second direction. Each of the plurality of blocks includes a first semiconductor layer extending in the first direction and opposed to the plurality of first layers. Among the plurality of blocks, a plurality of blocks excluding the first block closest to the third stacked structure includes a first conductive layer in the first layer. The third stacked structure and the first block include a second insulating layer as the first layer.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a predetermined plane may be referred to as a first direction, a direction along this predetermined plane and intersecting with the first direction may be referred to as a second direction, and a direction intersecting with the first direction and the second direction may be referred to as a third direction. These first direction, second direction, and third direction may each correspond to any of the Z-direction, the Y-direction, and the X-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

In this specification, when referring to a “wiring”, this may include a wiring, a via-contact electrode, a connecting portion for connecting a wiring to a via-contact electrode, a bonding electrode, or the like.

### First Embodiment

### [Circuit Configuration of Memory Die MD]

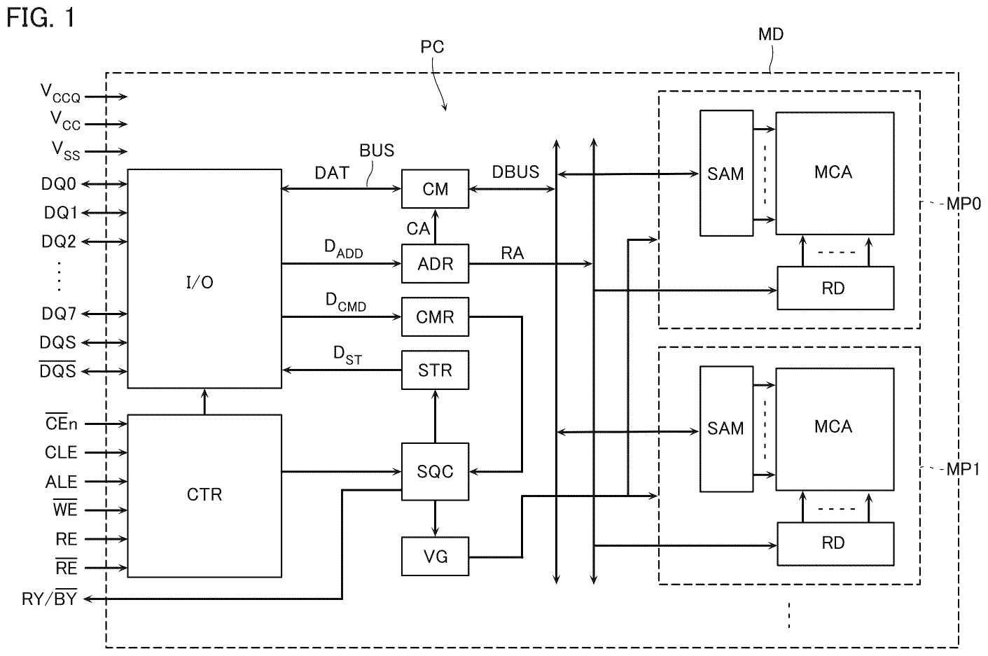

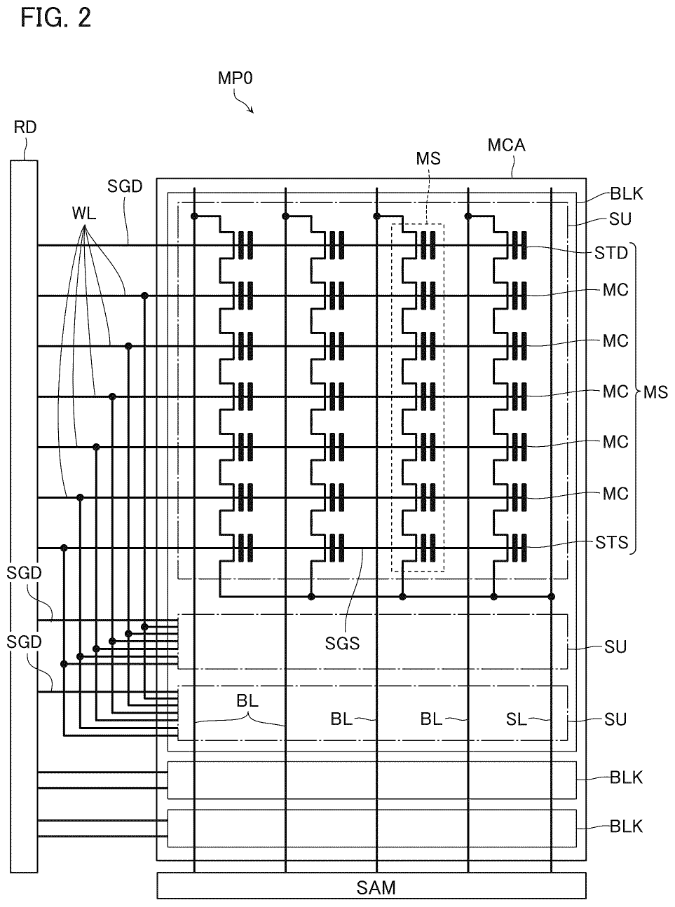

FIG. 1 is a schematic block diagram illustrating a configuration of a memory die MD according to a first embodiment. FIG. 2 is a schematic circuit diagram illustrating a part of the configuration of the memory die MD.

As illustrated in FIG. 1, the memory die MD includes a plurality of memory planes MP0, MP1, and the like, and a peripheral circuit PC. While in FIG. 1 the two memory planes MP10 and MP1 are illustrated, there may be more memory planes MPn. The peripheral circuit PC includes a voltage generation circuit VG and a sequencer SQC. The peripheral circuit PC also includes a cache memory CM, an address register ADR, a command register CMR, and a status register STR. The peripheral circuit PC also includes an input/output control circuit I/O and a logic circuit CTR.

### [Circuit Configuration of Memory Plane MP0]

As illustrated in FIG. 2, the memory plane MP0 includes a memory cell array MCA, a row decoder RD, and a sense amplifier module SAM. The memory plane MP1 is also configured in the same way. The memory cell array MCA includes a plurality of memory blocks BLK. Each of these plurality of memory blocks BLK includes a plurality of string units SU. Each of these plurality of string units SU includes a plurality of memory strings MS. The plurality of memory strings MS have one ends each connected to the sense amplifier module SAM via a bit line BL. These plurality of memory strings MS have the other ends each connected to the sense amplifier module SAM via a common source line SL.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores data of 1 bit or a plurality of bits. Respective word lines WL are connected to the gate electrodes of the plurality of memory cells MC corresponding to one memory string MS. Each of these word lines WL is connected in common to all of the memory strings MS in one memory block BLK.

The select transistors (STD, STS) are a field-effect type transistor. The select transistors (STD, STS) include a semiconductor layer, a gate insulating film, and a gate electrode. The semiconductor layer functions as a channel region. The gate insulating film may include an electric charge accumulating layer. The select gate lines (SGD, SGS) are connected to the gate electrodes of the select transistors (STD, STS), respectively. One drain-side select gate line SGD is connected to all of the memory strings MS in one string unit SU in common. One source-side select gate line SGS is connected in common to all of the memory strings MS in one memory block BLK. The respective drain-side select gate line SGD and source-side select gate line SGS may be referred to as select gate lines SG.

The word lines WL and the select gate lines SG are connected to the row decoder RD. The row decoder RD applies the word lines WL and the select gate lines SG with predetermined control voltages.

Here, while the circuit configuration of the memory plane MP0 is described, the other memory planes MP1, and the like are also configured in the same way.

### [Structure of Memory Die MD]

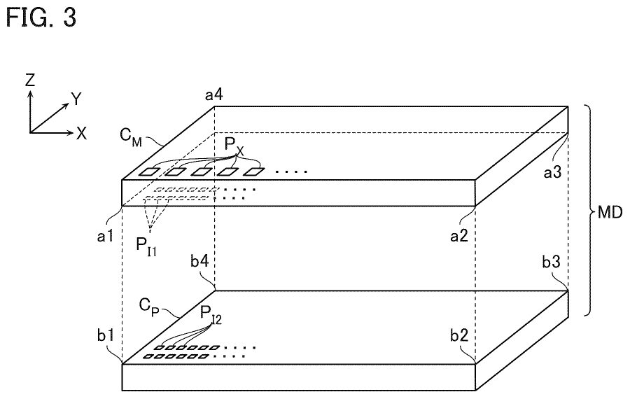

FIG. 3 is a schematic exploded perspective view illustrating an exemplary configuration of a semiconductor memory device according to the first embodiment. As illustrated in FIG. 3, the memory die MD includes a chip C_{M} on the memory cell array MCA side and a chip C_{P} on the peripheral circuit PC, the sense amplifier module SAM, and the row decoder side.

An upper surface of the chip C_{M} includes a plurality of external pad electrodes P_{X} enabled to be connected to bonding wires, which are not illustrated. A lower surface of the chip C_{M} includes a plurality of bonding electrodes P_{I1}. The upper surface of the chip C_{P} is provided with a plurality of bonding electrodes P_{I2}. In the following, a surface of the chip C_{M} on which the plurality of bonding electrodes P_{I1} are formed is referred to as a front surface, and a surface of the chip C_{M} on which the plurality of external pad electrodes P_{X} are formed is referred to as a back surface. In the case of the chip C_{P}, a surface on which the plurality of bonding electrodes P_{I2} are formed is referred to as a front surface, and a surface opposite to the front surface is referred to as a back surface. In the example of the figure, the front surface of the chip C_{P} is formed above the back surface of the chip C_{P}, and the back surface of the chip C_{M} is formed above the surface of the chip C_{M}.

The chip C_{M} and the chip C_{P} are arranged such that the front surface of the chip C_{M} and the front surface of the chip C_{P} are opposed one another. The plurality of bonding electrodes P_{I1} are provided in correspondence with the plurality of bonding electrodes P_{I2}, and are arranged in positions where they are allowed to be bonded to the plurality of bonding electrodes P_{I2}. The bonding electrode P_{I1} and the bonding electrode P_{I2} function as bonding electrodes for bonding the chip C_{M} and the chip C_{P} and allowing electrical conduction.

In the example in FIG. 3, corner portions a1, a2, a3, and a4 of the chip C_{M} correspond to corner portions b1, b2, b3, and b4 of the chip C_{P}, respectively.

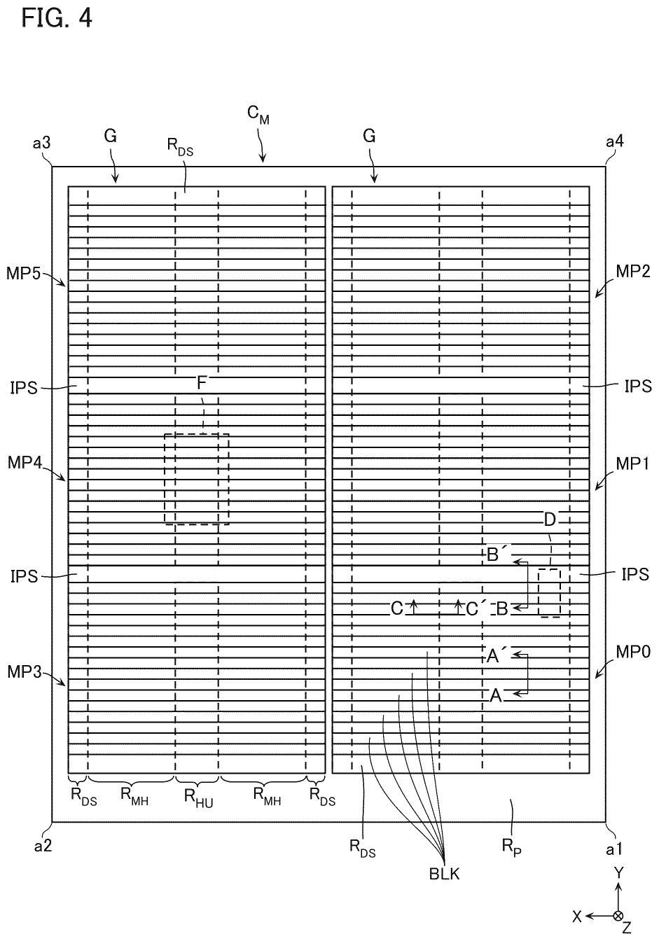

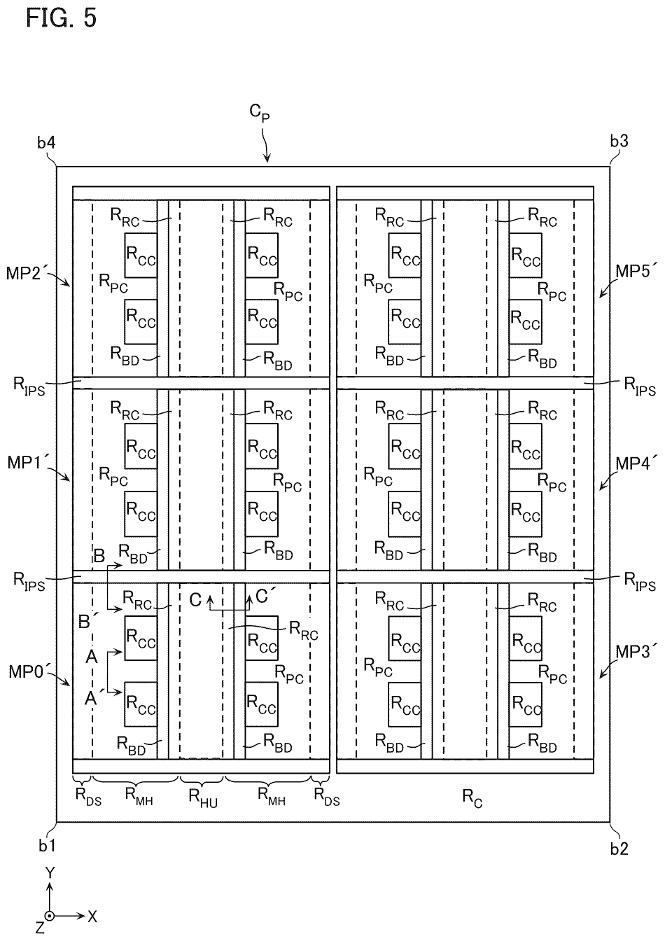

FIG. 4 is a schematic bottom view illustrating an exemplary configuration of the chip C_{M}. In FIG. 4, parts of configurations, such as the bonding electrode P_{I1} and the like have been omitted. FIG. 5 is a schematic plan view illustrating an exemplary configuration of the chip C_{P}. In

FIG. 5, parts of configurations, such as the bonding electrode P_{I2} and the like have been omitted.

### [Planar Structure of Chip C_{M}]

In the example of FIG. 4, the chip C_{M} includes a total of six memory planes MP0 to MP5 in which two arranged in the X-direction and three arranged in the Y-direction. The six memory planes MP0 to MP5 are sometimes referred to simply as a memory plane MP.

Each interplanar structure IPS is provided between the memory plane MP0 and the memory plane MP1, between the memory plane MP1 and the memory plane MP2, between the memory plane MP3 and the memory plane MP4, and between the memory plane MP4 and the memory plane MP5. The interplanar structure IPS insulates and separates the memory planes MP that are adjacent to one another in the Y-direction. In this example, the memory plane MP0 and the memory plane MP1 and the interplanar structure IPS between the memory plane MP0 and the memory plane MP1 correspond to the first stacked structure, the second stacked structure, and the third stacked structure, respectively.

In addition, each of these six memory planes MP0 to MP5 includes a plurality of memory blocks BLK arranged in the Y-direction. In the example of FIG. 4, each of these six memory planes MP0 to MP5 includes memory hole regions R_{MH} (memory region) provided on both sides in the X-direction, and a hook-up region R_{HU} provided between the memory hole regions R_{MH}. In the example of FIG. 4, dummy staircase portions R_{DS} are provided on both sides of the memory hole regions R_{MH} in the X-direction and on the end portions close to both sides in the Y-direction of the chip C_{M} in the memory planes MP0, MP2, MP3, and MP5. The chip C_{M} also has a peripheral region R_{P} provided on one end side in the Y-direction of the six memory planes MP0 to MP5.

In the example of the figure, the hook-up region R_{HU} is provided in the center portion in the X-direction of the memory plane MP. However, this configuration is just an example, and the specific configuration can be adjusted as appropriate. For example, the hook-up region R_{HU} may be provided not in the center portion in the X-direction of the memory plane MP, but at one end portion or both end portions in the X-direction.

### [Planar Structure of Chip C_{P}]

The chip C_{P} corresponds to the chip C_{M}, as illustrated in FIG. 5, for example, and includes regions MP0′ to MP5′ overlapping with the six memory planes MP0 to MP5, which are arranged in two in the X-direction and three in the Y-direction. Each region Rips overlapping with the interplanar structure IPS is provided between the region MP0′ and the region MP1′, between the region MP1′ and the region MP2′, between the region MP3′ and the region MP4′, and between the region MP4′ and the region MP5′. In the center portion in the X-direction of these six regions MP0′ to MP5′, the row control circuit regions R_{RC} are provided. In addition, two block decoder regions R_{BD} are provided on both sides in the X-direction of the row control circuit region R_{RC}. In addition, peripheral circuit regions R_{PC} are provided outside in the X-direction of these two block decoder regions R_{BD}. In each peripheral circuit region R_{PC}, two column control circuit regions R_{CC} arranged in the Y-direction are provided. In addition, although they are not illustrated, there are also circuits arranged in other regions within the peripheral circuit region R_{PC}. In addition, in the region of the chip C_{P} opposed to the peripheral region R_{P} of the chip C_{M} (FIG. 4), a circuit region R_{C} is provided.

[Cross-Sectional Structures of Chips C_{M}, C_{P}]

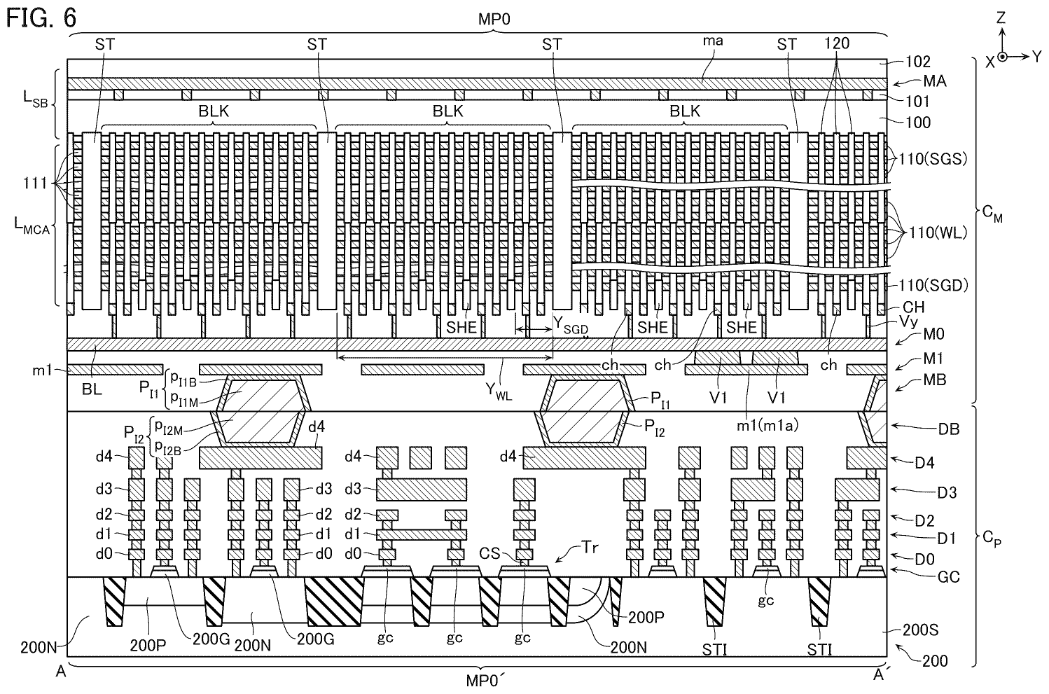

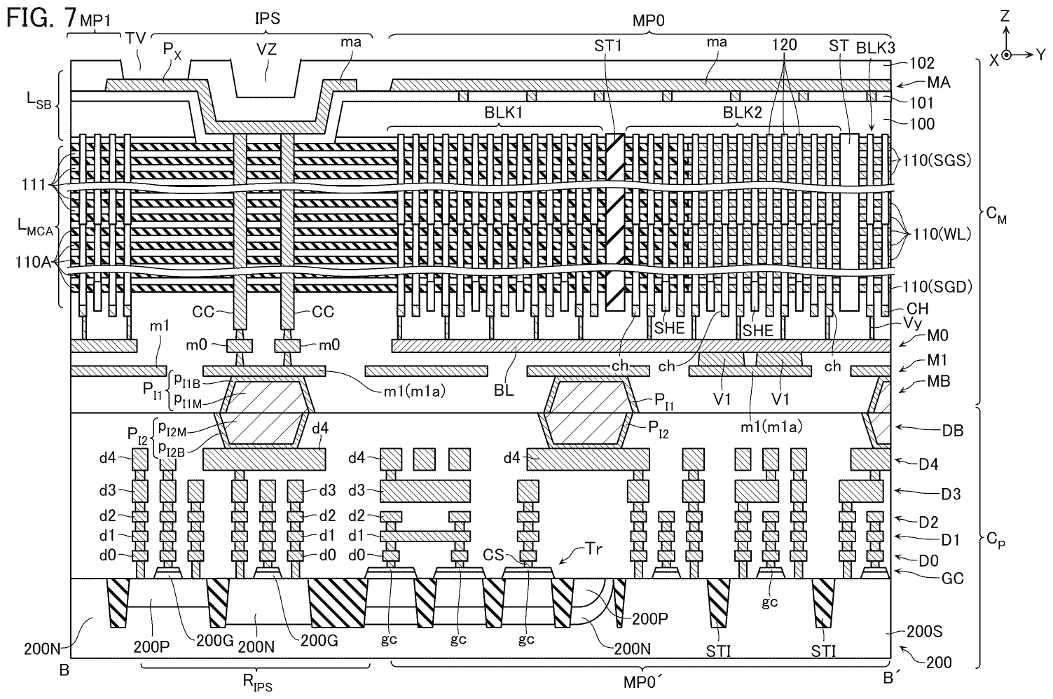

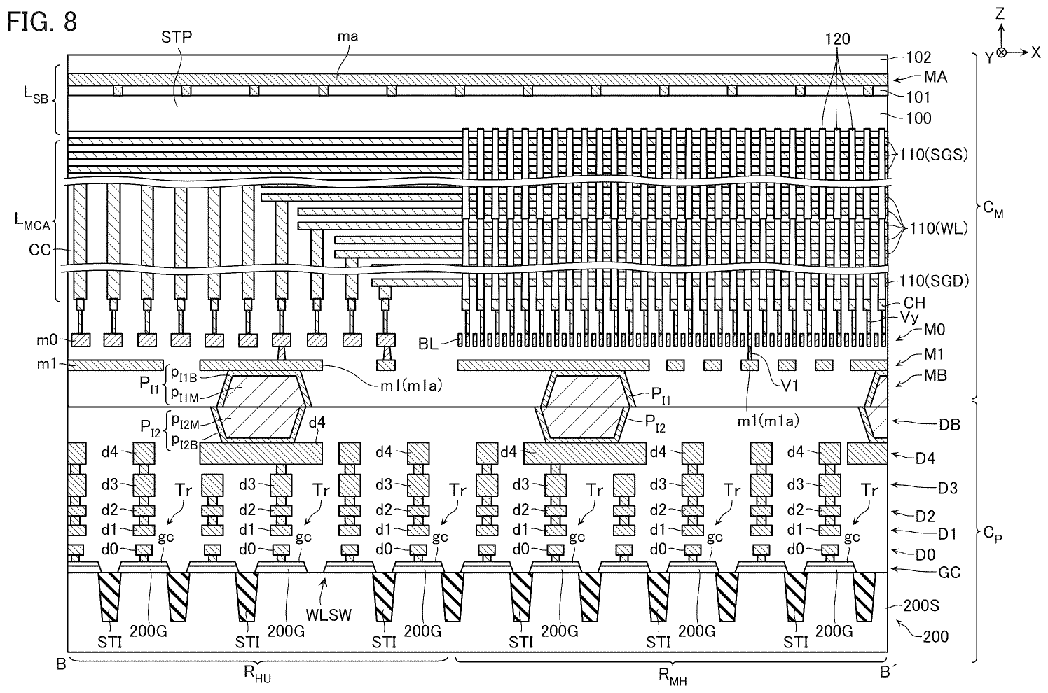

FIGS. 6, 7 and 8 are schematic cross-sectional views illustrating configurations of parts of the memory die MD. FIG. 6 is the schematic cross-sectional view of the memory die MD cut along the A-A′ line in FIGS. 4 and 5, as seen from the direction of the arrow. FIG. 7 is the schematic cross-sectional view of the memory die MD cut along the B-B′ line in FIGS. 4 and 5, as seen from the direction of the arrow. FIG. 8 is the schematic cross-sectional view of the memory die MD cut along the C-C′ line in FIGS. 4 and 5, as seen from the direction of the arrow.

### [Cross-Sectional Structure of Chip C_{M}]

The chip C_{M}, for example, as illustrated in FIGS. 6 to 8, includes a base layer L_{SB}, a memory cell array layer L_{MCA} provided under the base layer L_{SB}, a via-contact electrode layer CH provided under the memory cell array layer L_{MCA}, a plurality of wiring layers M0 and M1 provided below the via-contact electrode layer CH, and a chip bonding electrode layer MB provided under the wiring layers M0 and M1.

[Cross-Sectional Structure of Base Layer L_{SB} Chip C_{M}]

For example, as illustrated in FIGS. 6 to 8, the base layer L_{SB} includes a conductive layer 100 provided on an upper surface of the memory cell array layer L_{MCA}, an insulating layer 101 provided on an upper surface of the conductive layer 100, a back side wiring layer MA provided on an upper surface of the insulating layer 101, and an insulating layer 102 provided on an upper surface of the back side wiring layer MA.

The conductive layer 100 may include a semiconductor layer such as silicon (Si) into which N-type impurities such as phosphorus (P) or P-type impurities such as boron (B) have been implanted, or it may contain a metal such as tungsten (W), or it may contain a silicide such as tungsten silicide (WSi).

The conductive layer 100 functions as a part of the source line SL (FIG. 2). The four conductive layers 100 are provided corresponding to the four memory planes MP0 to MP3 (FIG. 4). The end portions of the memory planes MP in the X-direction and the Y-direction are provided with a region VZ that does not include the conductive layer 100.

The insulating layer 101 includes, for example, silicon oxide (SiO₂).

The back side wiring layer MA includes a plurality of wirings ma. These plurality of wirings ma may contain, for example, aluminum (Al) or other materials.

A part of the plurality of wirings ma function as a part of the source line SL (FIG. 2). For example, four of these wirings ma are provided to correspond to the four memory planes. Each of these wirings ma is electrically connected to the conductive layer 100.

In addition, parts of the plurality of wirings ma function as the external pad electrodes P_{X}. This wiring ma is provided in the peripheral region R_{P}. This wiring ma is connected to the via-contact electrode CC in the memory cell array layer L_{MCA} in the region VZ that does not include the conductive layer 100. In addition, a part of the wiring ma is exposed outside the memory die MD via an opening TV provided in the insulating layer 102.

The insulating layer 102 is a passivation layer made of an insulating material such as polyimide.

[Structure of Memory Plane MP0 in Memory Cell Array Layer L_{MCA} of Chip C_{M}]

As illustrated in FIG. 6, the memory cell array layer L_{MCA} includes a plurality of memory blocks BLK arranged in the Y-direction. An inter-block insulating layer ST, such as silicon oxide (SiO₂), is provided between two memory blocks BLK that are adjacent to one another in the Y-direction. The inter-block insulating layer ST may also include a conductive layer including a barrier conductive film, such as titanium nitride film (TiN), and a metal film, such as tungsten (W), on an insulating film, such as silicon oxide (SiO₂).

The memory block BLK includes a plurality of conductive layers 110 and interlayer insulating layers 111 arranged alternately in the Z-direction, and a plurality of semiconductor layers 120 extending in the Z-direction.

The conductive layer 110 has an approximately plate shape extending in the X-direction. The conductive layer 110 may include a stacked film and the like of a barrier conductive film, such as titanium nitride film (TiN), and a metal film, such as tungsten (W) or molybdenum (Mo). The conductive layer 110 may also include polycrystalline silicon and the like containing impurities such as phosphorus (P), boron (B), or the like. The interlayer insulating layer 111, which is arranged between the plurality of conductive layers 110 arranged in the Z-direction, may include silicon oxide (SiO₂) and the like.

Among the plurality of conductive layers 110, one or a plurality of conductive layers 110 positioned on an uppermost layer function as a gate electrode of the source-side select transistor STS (FIG. 2) and the source-side select gate line SGS. These plurality of conductive layers 110 are electrically independent for each memory block BLK.

Additionally, a plurality of conductive layers 110 positioned below this conductive layer 110 function as a gate electrode of the memory cell MC (FIG. 2) and the word line WL. These plurality of conductive layers 110 (WL) are each electrically independent for each memory block BLK.

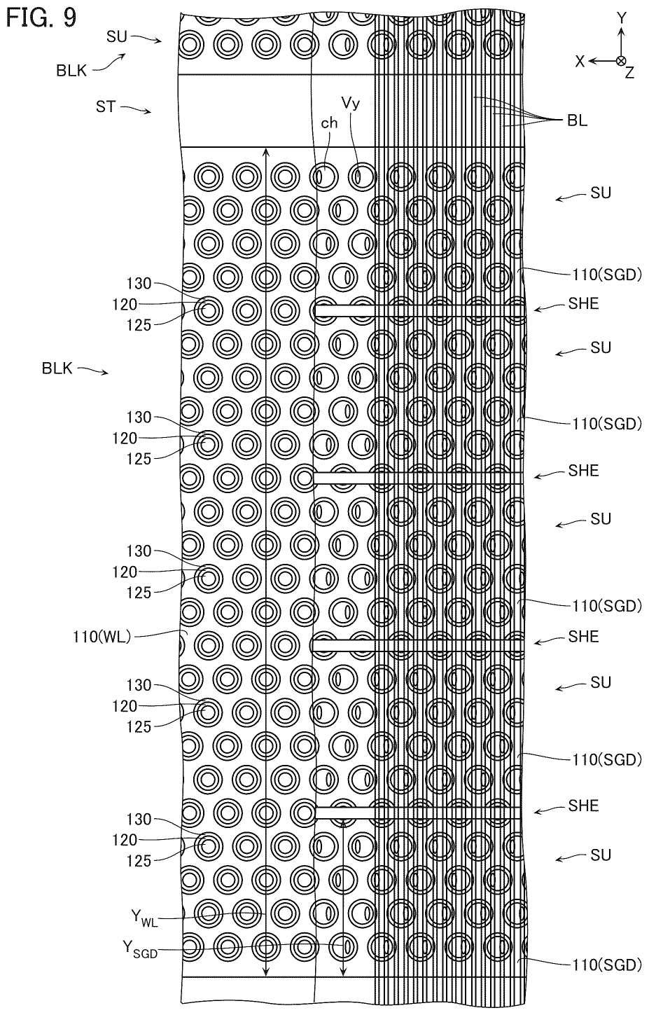

One or a plurality of conductive layers 110 positioned below the conductive layers 110 function as a gate electrode of the drain-side select transistor STD and the drain-side select gate line SGD. A width Y_{SGD} in the Y-direction of these plurality of conductive layers 110 is smaller than a width Y_{WL} in the Y-direction of the conductive layers 110 that function as the word lines WL (also illustrated in FIG. 9). In addition, an inter-string unit insulating layer SHE, such as silicon oxide (SiO₂), is provided between two conductive layers 110 adjacent to one another in the Y-direction.

FIG. 9 is an enlarged back view of a part of the memory block BLK in FIG. 6 viewed in the Z-direction. A right side of FIG. 9 illustrates a layer closest to the semiconductor substrate 200 of the memory cell array layer L_{MCA}, and a left side illustrates an intermediate layer of the memory cell array layer L_{MCA}.

As illustrated in FIG. 9, the semiconductor layers 120 are arranged in a predetermined pattern in the X-direction and the Y-direction. The respective semiconductor layers 120 function as the channel regions of the plurality of memory cells MC and the select transistors (STD, STS) included in one memory string MS (FIG. 2). The semiconductor layer 120 contains, for example, polycrystalline silicon (Si) or the like. The semiconductor layer 120 has an approximately cylindrical shape, and an insulating layer 125 of silicon oxide or the like is disposed in a center portion. Outer peripheral surfaces of the semiconductor layers 120 are each surrounded by the plurality of conductive layers 110 and opposed to these plurality of conductive layers 110.

Additionally, on an upper end of the semiconductor layer 120, an impurity region (not illustrated) is disposed. This impurity region is connected to the conductive layer 100 (see FIG. 7). This impurity region, for example, contains N-type impurities, such as phosphorus (P), and P-type impurities, such as boron (B).

On a lower end of the semiconductor layer 120, an impurity region (not illustrated) is disposed. This impurity region is connected to the bit line BL via a via-contact electrode ch and a via-contact electrode Vy. The impurity region contains N-type impurities, such as phosphorus (P).

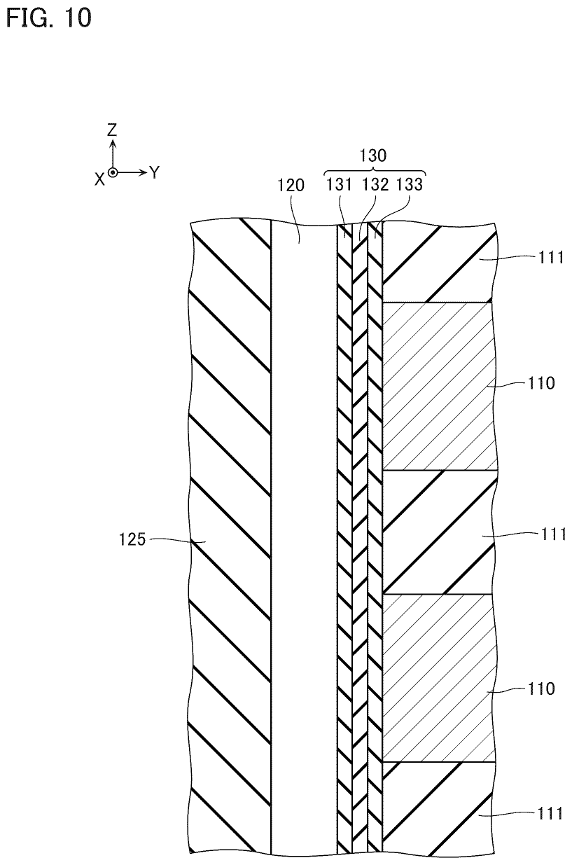

FIG. 10 is an enlarged schematic cross-sectional view illustrating a part of FIG. 6. A gate insulating film 130 has an approximately cylindrical shape covering an outer peripheral surface of the semiconductor layer 120. The gate insulating film 130 includes a tunnel insulating film 131, an electric charge accumulating film 132, and a block insulating film 133, which are stacked between the semiconductor layer 120 and the conductive layers 110. The tunnel insulating film 131 and the block insulating film 133 include, for example, silicon oxide (SiO₂), silicon oxynitride (SiON), and the like. The electric charge accumulating film 132 includes a film of silicon nitride (SiN) or the like that allows accumulation of electric charge. The tunnel insulating film 131, the electric charge accumulating film 132, and the block insulating film 133, which have approximately cylindrical shapes, extend in the Z-direction along the outer peripheral surface of the semiconductor layer 120 excluding contact portions with the semiconductor layer 120 and the conductive layer 100.

FIG. 10 illustrates an example in which the gate insulating film 130 includes the electric charge accumulating film 132 of silicon nitride or the like. However, the gate insulating film 130 may, for example, include a floating gate of, for example, polycrystalline silicon containing N-type or P-type impurities.

[Interplanar Structure IPS and Surrounding Structure of Memory Cell Array Layer L_{MCA} of Chip C_{M}]

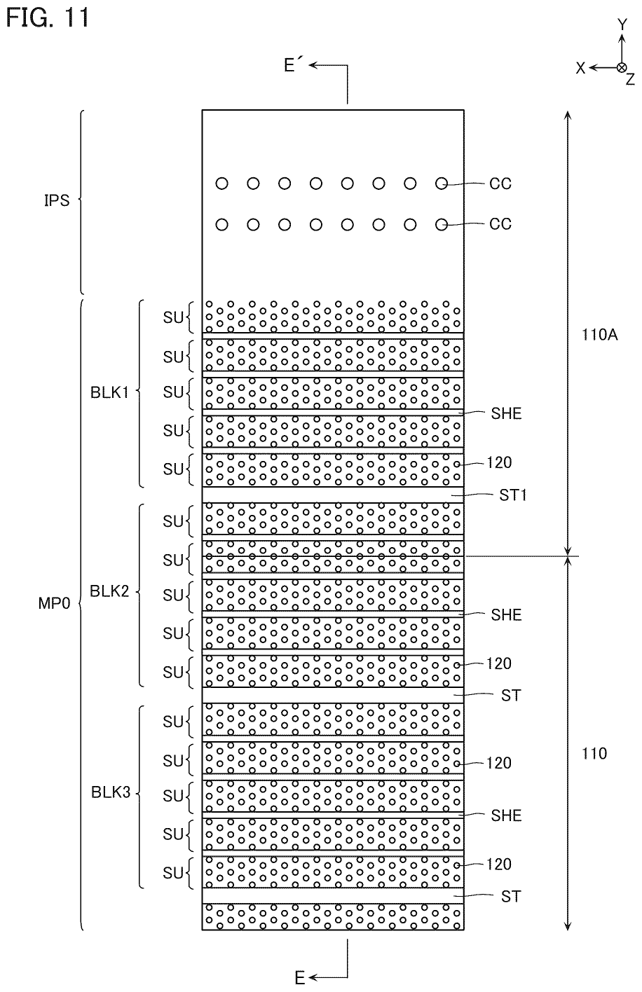

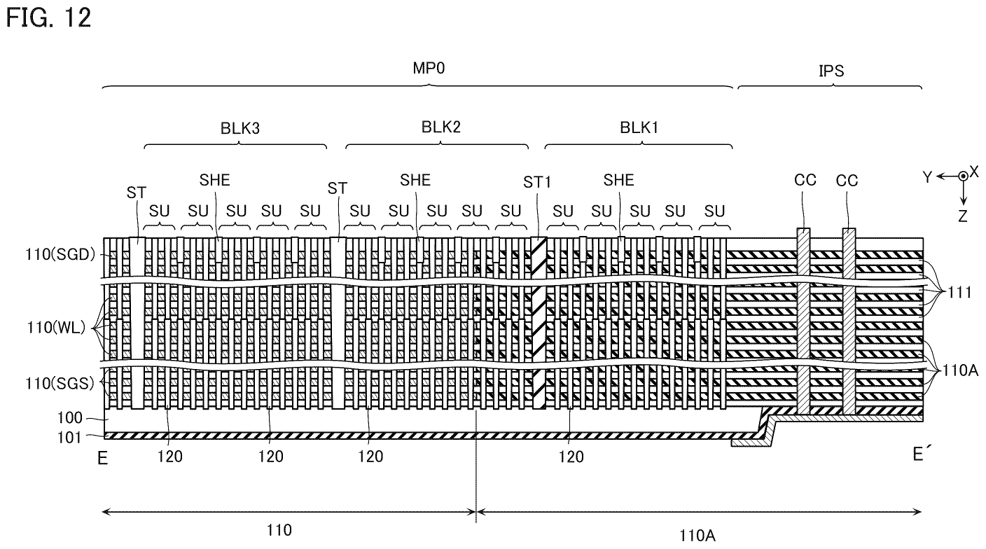

In addition to FIG. 7, FIGS. 11 and 12 are referred. FIG. 11 is an enlarged plan view of the portion of the chip C_{M} indicated by D in FIG. 4. FIG. 12 is a cross-sectional view of a part of the base layer L_{SB} of the chip C_{M} and the memory cell array layer L_{MCA} cut along the line E-E′ of FIG. 11 viewed along the arrow direction. As illustrated in FIG. 7, an interplanar structure IPS (third stacked structure) is provided between the memory plane MP0 (first stacked structure) and the memory plane MP1 (second stacked structure). The first memory block BLK1 (first block), which is closest to the interplanar structure IPS of each of the memory planes MP0 and MP1, and the second memory block BLK2 (second block), which is second closest to the interplanar structure IPS, are dummy blocks that are not used as a memory. The third memory block BLK3, which is the third closest to the interplanar structure IPS, can be used as a normal memory block BLK or as a dummy block.

The first memory block BLK1 includes a plurality of insulating layers 110A (second insulating layer) and interlayer insulating layers 111 arranged alternately in the Z-direction, and a plurality of semiconductor layers 120 extending in the Z-direction.

On the side close to the interplanar structure IPS, the second memory block BLK2 includes a plurality of insulating layers 110A and interlayer insulating layers 111 arranged alternately in the Z-direction, and a plurality of semiconductor layers 120 extending in the Z-direction. On the side far from the interplanar structure IPS, the second memory block BLK2 includes a plurality of conductive layers 110 (first conductive layer) and interlayer insulating layers 111 arranged alternately in the Z-direction, and a plurality of semiconductor layers 120 extending in the Z-direction.

The interplanar structure IPS includes a plurality of insulating layers 110A and interlayer insulating layers 111 arranged alternately in the Z-direction, and a plurality of via-contact electrodes CC extending in the Z-direction. One end of the via-contact electrode CC penetrates the insulating layer 101 and is connected to the external pad electrode P_{X} via the wiring ma. The other end of the via-contact electrode CC is connected to the bonding electrode P_{I1} via a wiring m0 and a wiring m1. The conductive layer 100 of the memory plane MP0 and the conductive layer 100 of the memory plane MP1 are insulated and separated in the Y-direction by the insulating layer 101 at the position of the interplanar structure IPS.

In this configuration, the insulating layer 110A includes, for example, silicon nitride (SiN). The insulating layer 110A and the conductive layer 110 are arranged in the same layer in the memory cell array layer L_{MCA}, and form a plurality of first layers. As illustrated in FIGS. 11 and 12, the first layer includes an insulating layer 110A formed in an interplanar structure IPS, a first memory block BLK1, and a part of a side close to an interplanar structure IPS of the second memory block BLK2; and a conductive layer 110 formed on a part of a far side of the second memory block BLK2 from the interplanar structure IPS, a third memory block BLK3, and other memory blocks BLK.

An inter-block insulating layer ST1 (fourth insulating layer) is provided between the first memory block BLK1 and the second memory block BLK2. The inter-block insulating layer ST1 extends in the X-direction and the Z-direction and divides a space between the first memory block BLK1 and the second memory block BLK2 in the Y-direction. The inter-block insulating layer ST1 may, for example, contain silicon oxide (SiO₂). The inter-block insulating layer ST1 may be made of the same material as the other inter-block insulating layers ST (third insulating layer) or a different material, as long as it is resistant to liquid or gaseous etchant used to etch the insulating layer 110A.

[Structure of Hook-Up Region R_{HU} in Memory Cell Array Layer L_{MCA} of Chip C_{M}]

As illustrated in FIG. 8, a staircase section STP is formed in the hook-up region R_{HU}, and the staircase portion STP has different lengths in the X-direction of the conductive layers 110 (WL, SGD, SGS) for the drain-side select gate line SGD, the word line WL, and the source-side select gate line SGS. The hook-up region R_{HU} includes a plurality of via-contact electrodes CCs. Each of these plurality of via-contact electrode CCs extends in the Z-direction and is connected to the conductive layer 110 (WL, SGD, SGS) of the staircase portion STP at an upper end thereof.

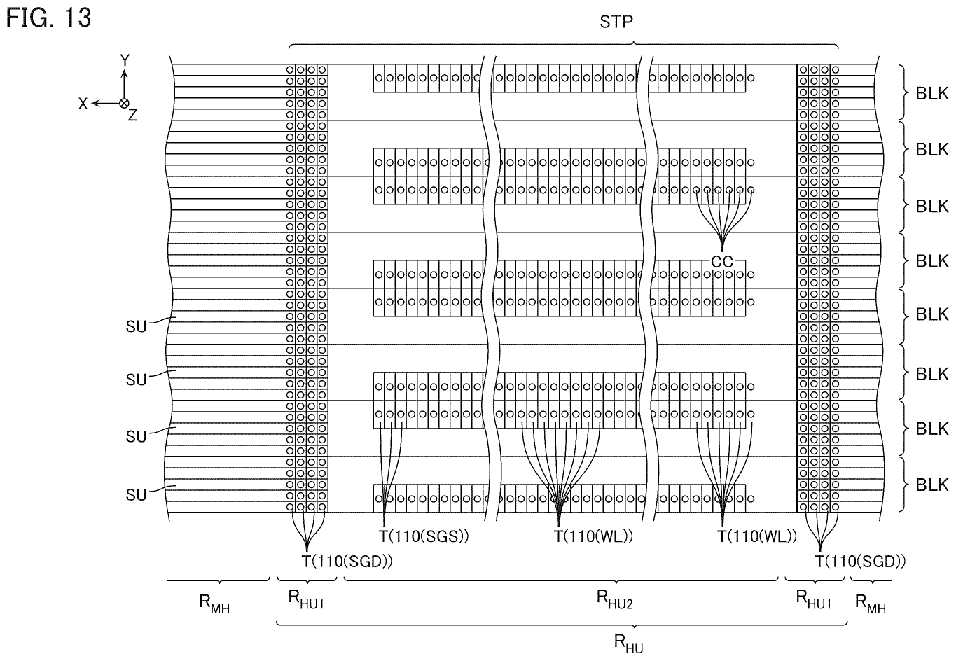

FIG. 13 is an enlarged schematic plan view illustrating a part indicated by F in FIG. 4. The hook-up region R_{HU} includes a first hook-up region R_{HU1} in which terrace portions T (110 (SGD)) connected to the drain-side select gate line SGD are arranged on both sides in the X-direction. The hook-up region R_{HU} also includes a second hook-up region R_{HU2} on the center portion in the X-direction, which includes terrace portions T (110 (WL)) connected to the word line WL and terrace portions T (110 (SGS)) connected to the source-side select gate line SGS. The via-contact electrode CC connected to the drain-side select gate line SGD is provided for each string unit SU. The via-contact electrodes CC connected to the word lines WL and the source-side select gate line SGS are provided for each memory block BLK.

[Structure in Peripheral Region R_{P} of Memory Cell Array Layer L_{MCA} of Chip C_{M}]

In the peripheral region R_{P}, the plurality of via-contact electrodes CC are provided corresponding to the external pad electrode P_{X}. These plurality of via-contact electrodes CC are connected to the external pad electrodes P_{X} at the upper end.

### [Structure of Via-Contact Electrode Layer CH]

The plurality of via-contact electrodes ch included in the via-contact electrode layer CH are electrically connected to at least one of the configuration in the memory cell array layer L_{MCA} and the configuration in the chip C_{P}, for example.

The via-contact electrode layer CH includes the plurality of via-contact electrodes ch as a plurality of wirings. These plurality of via-contact electrodes ch may include a stacked film of a barrier conductive film, such as titanium nitride (TiN), and a metal film, such as tungsten (W), for example. The via-contact electrodes ch are provided in correspondence with the plurality of semiconductor layers 120 and are connected to the lower ends of the plurality of semiconductor layers 120.

### [Structure of Wiring Layers M0 and M1 in Chip C_{M}]

The plurality of wires included in the wiring layers M0 and M1 are electrically connected to at least one of the configuration in the memory cell array layer L_{MCA} and the configuration in the chip C_{P}, for example.

The wiring layer M0 includes a plurality of the wirings m0. These plurality of wirings m0 may include, for example, a stacked film of a barrier conductive film made of, such as titanium nitride (TiN), tantalum nitride (TaN), and a stacked film of tantalum nitride (TaN) and tantalum (Ta); and a metal film made of, such as copper (Cu). In addition, a part of the plurality of wirings m0 function as bit lines BL. The bit lines BL, for example, are arranged in the X-direction and extended in the Y-direction.

The wiring layer M1 includes a plurality of the wirings m1, as illustrated in FIG. 6, for example. These plurality of wirings m1 may include a stacked film and the like of a barrier conductive film, such as titanium nitride film (TiN), and a metal film, such as tungsten (W), for example.

### [Structure of Chip Bonding Electrode Layer MB]

The plurality of wiring layers included in the chip bonding electrode layer MB are electrically connected to at least one of the configuration in the memory cell array layer L_{MCA} and the configuration in the chip C_{P}, for example.

The chip bonding electrode layer MB includes a plurality of bonding electrodes P_{I1} (bonding pads). These plurality of bonding electrodes P_{I1} may include, for example, a stacked film of a barrier conductive film p_{I1B} made of, such as titanium nitride (TiN), tantalum nitride (TaN), and a stacked film of tantalum nitride (TaN) and tantalum (Ta); and a metal film p_{I1M} made of, such as copper (Cu).

### [Cross-Sectional Structure of Chip C_{P}]

The chip C_{P}, for example, as illustrated in FIG. 6, includes a semiconductor substrate 200, a gate electrode layer GC formed above the semiconductor substrate 200, the wiring layers D0, D1, D2, D3, and D4 formed above the gate electrode layer GC, and a chip bonding electrode layer DB formed on the wiring layers D0, D1, D2, D3, and D4.

### [Structure of Semiconductor Substrate 200 of Chip C_{P}]

The semiconductor substrate 200 contains, for example, P-type silicon (Si) containing P-type impurities, such as boron (B). The semiconductor substrate 200 includes a main surface SM on a side of the gate electrode layer GC and the wiring layers D0, D1, D2, D3, and D4. On a surface of the main surface SM side of the semiconductor substrate 200, an N-type diffusion layer 200N containing N-type impurities such as phosphorus (P), a P-type diffusion layer 200P containing P-type impurities such as boron (B), a semiconductor substrate region 200S where the N-type diffusion layer 200N and the P-type diffusion layer 200P are not provided, and an insulating layer ST1 are provided. A part of the P-type diffusion layer 200P is provided in the semiconductor substrate region 200S, and a part of the P-type diffusion layer 200P is provided in the N-type diffusion layer 200N. The N-type diffusion layer 200N, the P-type diffusion layer 200P provided on the N-type diffusion layer 200N and the semiconductor substrate region 200S, and the semiconductor substrate region 200S each function as parts of the plurality of transistors Tr, the plurality of capacitors, and the like constituting the peripheral circuit PC. Note that parts of the plurality of transistors Tr function as the word line switches WLSW and the select gate line switches SGSW.

### [Structure of Electrode Layer GC of Chip C_{P}]

The electrode layer GC is provided on an upper surface of the semiconductor substrate 200 via an insulating layer 200G. The electrode layer GC includes a plurality of electrodes gc opposed to the surface of the semiconductor substrate 200. Additionally, each region of the semiconductor substrate 200 and the plurality of electrodes gc included in the electrode layer GC are connected to respective via-contact electrodes CS.

The N-type diffusion layer 200N of the semiconductor substrate 200, the P-type diffusion layer 200P provided on the N-type diffusion layer 200N and the semiconductor substrate region 200S, and the semiconductor substrate region 200S each function as the channel regions of the plurality of transistors Tr, one electrodes of the plurality of capacitors, and the like constituting the peripheral circuit PC.

The plurality of electrodes gc included in the electrode layer GC each function as gate electrodes of the plurality of transistors Tr, the other electrodes of the plurality of capacitors, and the like constituting the peripheral circuit PC.

The via-contact electrodes CS extend in the Z-direction and have lower ends connected to an upper surface of the semiconductor substrate 200 or upper surfaces of the electrodes gc. The via-contact electrodes CS may include, for example, a stacked film of a barrier conductive film made of, such as titanium nitride (TiN) and a metal film made of, such as tungsten (W).

### [Structure of Wiring Layers D0, D1, D2, D3, and D4 of Chip C_{P}]

For example, as illustrated in FIG. 6, the plurality of connecting portions and the plurality of wirings included in the wiring Layers D0, D1, D2, D3, and D4 are electrically connected to at least one of the configurations in the memory cell array layer L_{MCA} and the configuration in the chip C_{P}.

The wiring layers D0, D1, and D2 each include a plurality of connecting portions d0, d1, and d2 and a plurality of wirings. These plurality of connecting portions d0, d1, d2 and the plurality of wirings may include, for example, a stacked film of a barrier conductive film made of, such as titanium nitride (TiN), and a metal film made of, such as tungsten (W).

The wiring layers D3 and D4 each include a plurality of connecting portions d3 and d4 and a plurality of wirings. These plurality of connecting portions d3, d4 and the plurality of wirings may include, for example, a stacked film of a barrier conductive film made of, such as titanium nitride (TiN), tantalum nitride (TaN), and a stacked film of tantalum nitride (TaN) and tantalum (Ta); and a metal film made of, such as copper (Cu).

### [Structure of Chip Bonding Electrode Layer DB]

These plurality of wiring layers included in the chip bonding electrode layer DB are electrically connected to at least one of the configuration in the memory cell array layer L_{MCA} and the configuration in the chip C_{P}, for example.

The chip bonding electrode layer DB includes the plurality of bonding electrodes P_{I2}. These plurality of bonding electrodes P_{I2} may include, for example, a stacked film of a barrier conductive film p_{I2B} made of, such as titanium nitride (TiN), tantalum nitride (TaN), and a stacked film of tantalum nitride (TaN) and tantalum (Ta); and a metal film p_{I2M} made of, such as copper (Cu).

When the bonding electrode P_{I1} and the bonding electrode P_{I2} employ the metal films p_{I1M} and p_{I2M} made of, such as copper (Cu), the metal film prim and the metal film p_{I2M} become integrated, thus making it difficult to confirm a boundary therebetween. However, the bonded structure can be confirmed due to a distortion of a bonded shape of the bonding electrode P_{I1} and the bonding electrode P_{I2} caused by misalignment of the bonding, and the misalignment of the barrier conductive films p_{I1B} and P_{I2B} (occurrence of discontinuity on a side). In addition, when the bonding electrode P_{I1} and the bonding electrode P_{I2} are formed using a damascene method, each side has a tapered shape. Therefore, a cross-sectional shape along the Z-direction at a point where the bonding electrode P_{I1} and the bonding electrode P_{I2} are bonded together does not have straight side walls, but is a non-rectangular shape. In addition, when the bonding electrode P_{I1} and the bonding electrode P_{I2} are bonded together, this forms a structure in which the barrier metal covers a bottom surface, side surfaces, and an upper surface of each Cu forming these. In contrast to this, in a wiring layer using a general Cu, an insulating layer (for example, SiN or SiCN) having an oxidation prevention function of Cu is disposed on an upper surface of the Cu, and the barrier metal is not disposed. In view of this, even when any positional shift of bonding is not generated, the distinction from a general wiring layer is possible.

### [Manufacturing Method of Memory Die MD]

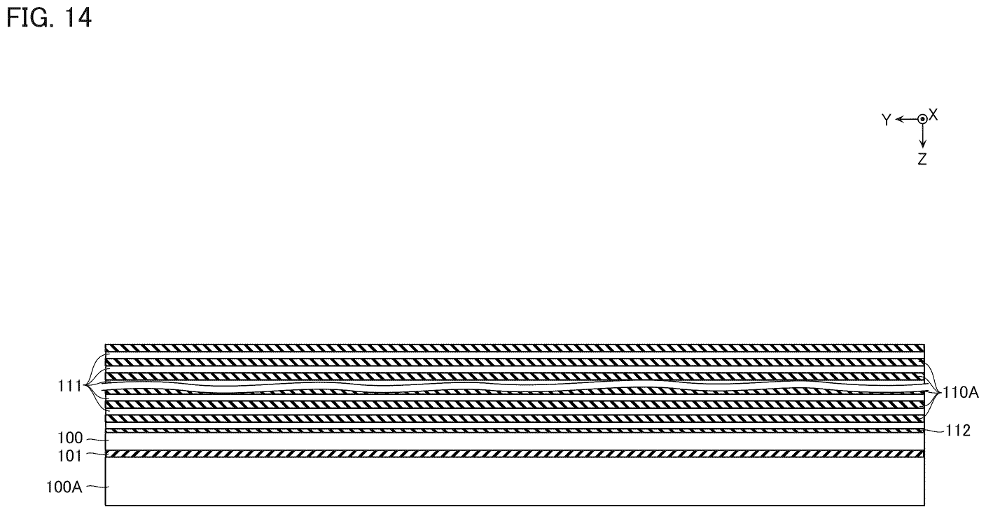

Next, with reference to FIG. 14 to FIG. 26, a method of manufacturing the memory die MD is described. FIG. 14 to FIG. 26 are schematic cross-sectional views for describing the manufacturing method. FIG. 14 to FIG. 26 illustrate cross-sectional surfaces corresponding to the cross-section illustrated FIG. 12.

In manufacturing the memory die MD in this embodiment, for example, as illustrated in FIG. 14, the insulating layer 101 made of, such as silicon oxide (SiO₂), is formed on a semiconductor substrate 100A of the chip C_{M}. In this process, for example, the insulating layer 101 is formed by a method, such as chemical vapor deposition (CVD).

Next, the conductive layer 100 and an insulating layer 112 are formed on an upper surface of the insulating layer 101. The conductive layer 100 may include polycrystalline silicon and the like, which contains N-type impurities, such as phosphorus (P) or P-type impurities, such as boron (B), for example. The conductive layer 100 may contain a metal, such as tungsten (W), or may contain a silicide, such as tungsten silicide (WSi). The insulating layer 112 may, for example, contain silicon nitride (SiN). This process is performed using a method, such as CVD.

Next, on an upper surface of the insulating layer 112, a plurality of insulating layers 110A and interlayer insulating layers 111 corresponding to a half of the memory cell array layer L_{MCA} are stacked alternately. The insulating layer 110A may, for example, contain silicon nitride (SiN) or the like. The interlayer insulating layer 111 may, for example, be made of a different material from the insulating layer 110A and may contain silicon oxide (SiO₂) or the like. For example, this process is performed by a method, such as CVD.

Next, although it is not illustrated in the figure, a part corresponding to the hook-up region R_{HU} of the plurality of insulating layers 110A and the interlayer insulating layers 111 are removed, and the staircase portion STP is formed in only half of the total number of stacked layers. In this process, for example, a resist is formed to cover the three memory planes MP0 to MP2 and the memory planes MP3 to MP5 arranged in the Y-direction, as illustrated in G in FIG. 4. Next, a part of the insulating layer 110A is selectively removed using RIE, wet etching, or the like with this resist as a mask. Next, a part of the interlayer insulating layer 111 is selectively removed using RIE, wet etching, or the like with this resist as a mask. Next, a part of the resist is removed isotropically using wet etching or the like. In the same way, a part of the insulating layer 110A, a part of the interlayer insulating layer 111, and a part of the resist are successively removed. Next, an insulating layer (not illustrated in the figure), such as silicon oxide (SiO₂), is formed on the removed parts. This process is performed by a method, such as CVD, for example.

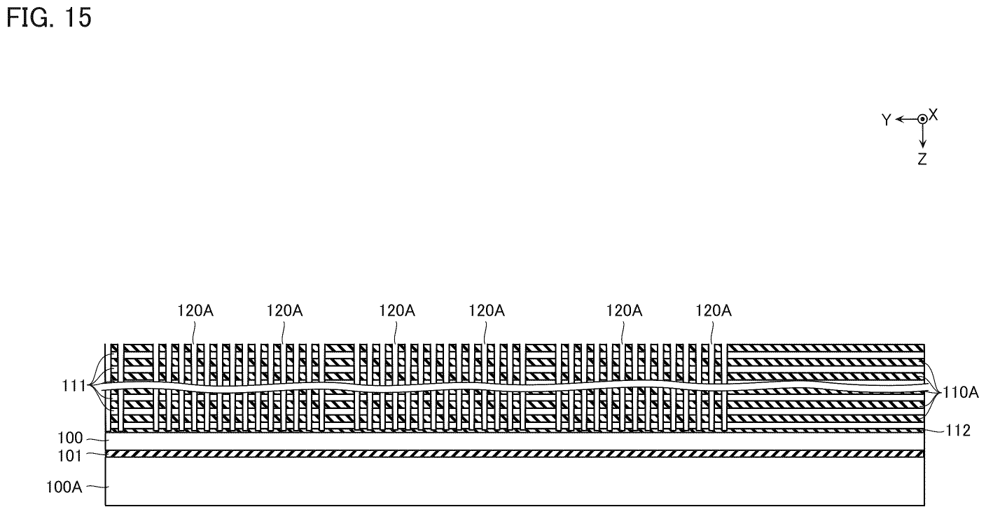

Next, as illustrated in FIG. 15, for example, a plurality of through-holes 120A is formed in positions corresponding to the semiconductor layers 120. The through-holes 120A are through-holes that extend in the Z-direction, penetrate the interlayer insulating layers 111 and the insulating layers 110A, and expose upper surfaces of the insulating layer 112. This process is performed by a method, such as RIE, for example.

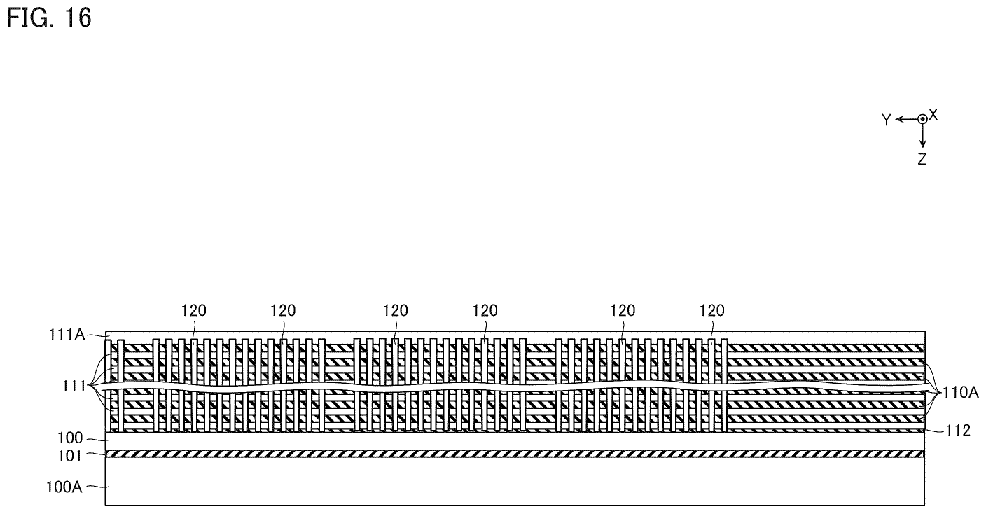

Next, as illustrated in FIG. 16, for example, the gate insulating film 130, the semiconductor layer 120, and the insulating layer 125 illustrated in FIG. 10 are formed on an inner peripheral surface of the through-hole 120A. Here, only the semiconductor layer 120, which will form a channel of a memory pillar, is illustrated. For example, this process is performed by a method, such as CVD. Next, an interlayer insulating layer 111A is formed on the semiconductor layer 120. For example, this process is performed by a method, such as CVD.

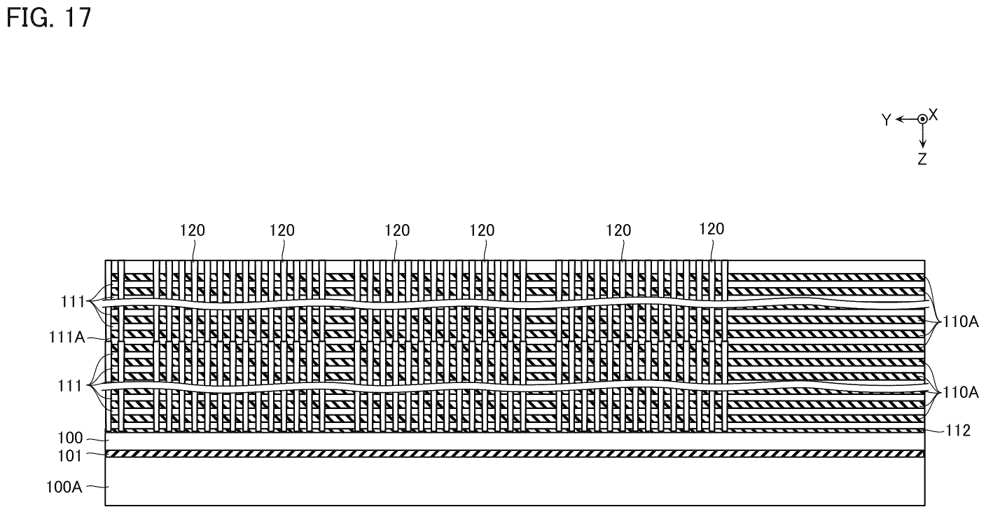

Next, as illustrated in FIG. 17, an upper surface of the interlayer insulating layer 111A is ground down using a method, such as CMP, until an upper surface of the semiconductor layer 120 is exposed, and then the plurality of insulating layers 110A and the interlayer insulating layers 111 corresponding to a remaining half of the memory cell array layer L_{MCA} are stacked alternately on top thereof. For example, this process is performed by a method, such as CVD.

Next, using the same method as described with reference to FIGS. 15 and 16, a structure corresponding to the remaining half of the memory cell array layer L_{MCA} is formed, and a plurality of semiconductor layers 120 are formed.

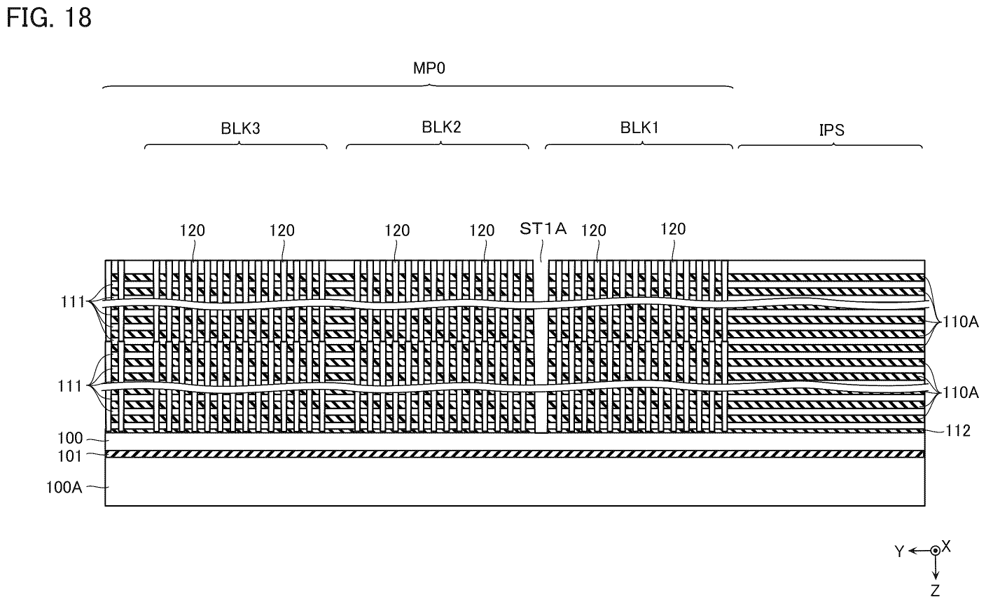

Next, as illustrated in FIG. 18, for example, a trench ST1A is formed at a boundary between the first memory block BLK1 and the second memory block BLK2. The trench ST1A extends in the Z-direction and the X-direction, divides the interlayer insulating layers 111, the insulating layers 110A, and the insulating layer 112 in the Y-direction, and exposes an upper surface of the conductive layer 100. This process is performed by, for example, a method, such as RIE.

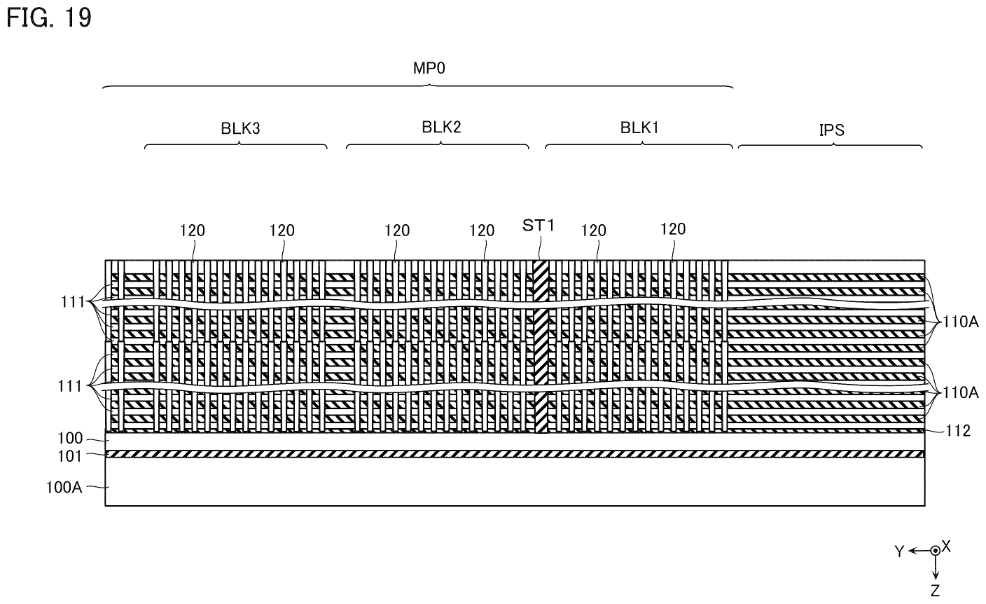

Next, for example, as illustrated in FIG. 19, the inter-block insulating layer ST1 is embedded in the trench ST1A. The inter-block insulating layer ST1 includes, for example, silicon oxide (SiO₂). For example, this process is performed by a method, such as CVD and CMP.

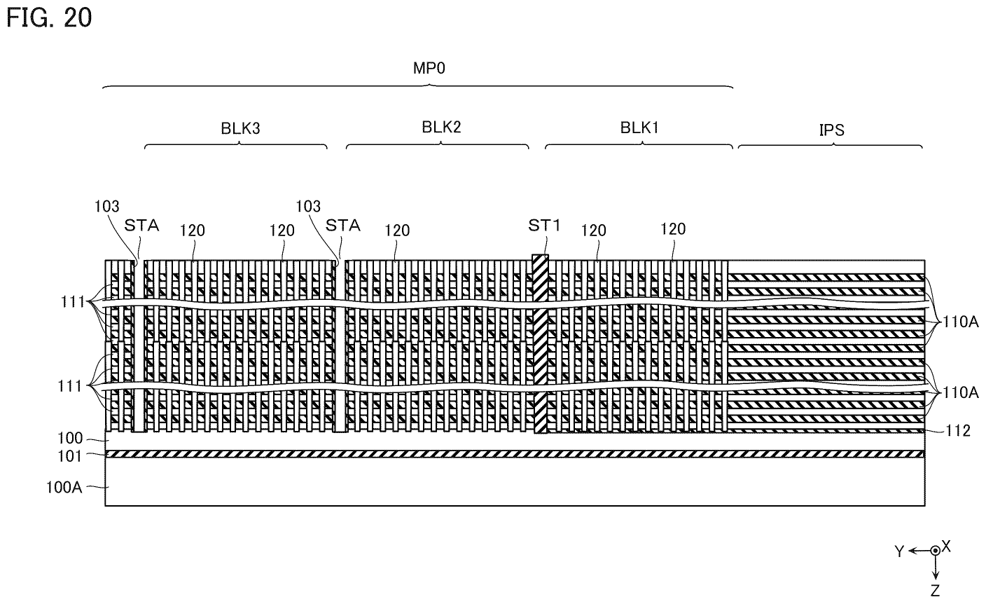

Next, as illustrated in FIG. 20, for example, the trenches STA are each formed between the memory blocks BLK, excluding the first memory block BLK1. The trench STA extends in the Z-direction and the X-direction, divides the interlayer insulating layers 111 and the insulating layers 110A in the Y-direction, and exposes an upper surface of the insulating layer 112. This process is performed by, for example, a method, such as RIE.

Next, for example, as illustrated in FIG. 20, a protective film 103 is formed on an inner wall of the trench STA, and a distal end portion of the trench STA is exposed to the insulating layer 112. This process is performed by a method, such as CVD and RIE.

Next, for example, as illustrated in FIG. 20, a part of the insulating layer 112 is removed through the trench STA to expose a part of the conductive layer 100. For example, this process is performed by a method, such as wet etching.

Next, as illustrated in FIG. 20, for example, a semiconductor layer is formed in an area where a part of the insulating layer 112 has been removed, and a new conductive layer 100 is formed. This connects a distal end portion of a source side of the semiconductor layer 120 to the conductive layer 100. For example, this process is performed by epitaxial growth and a method, such as RIE. Other methods, such as wet etching and CVD can also be used.

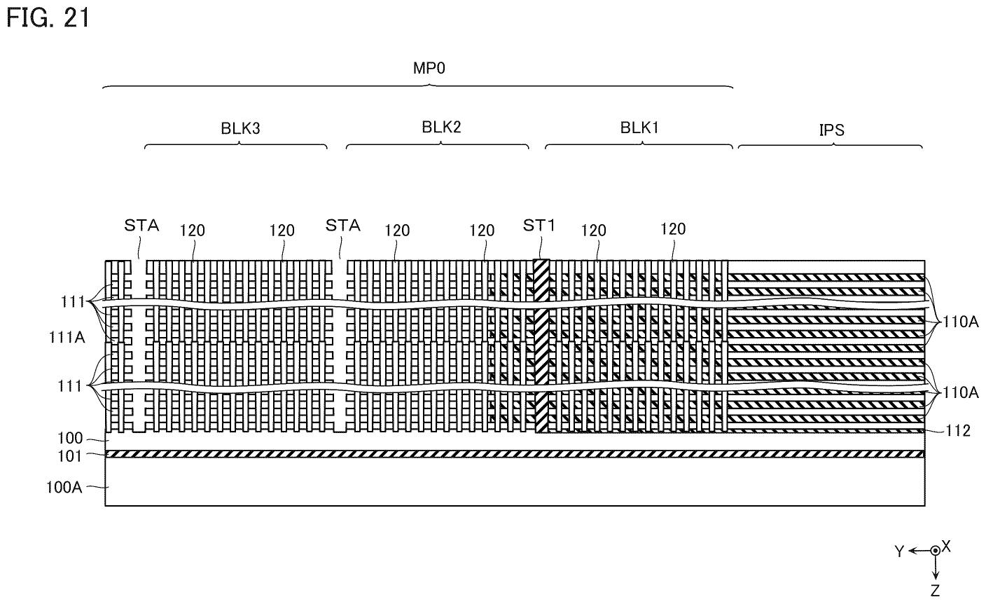

Next, for example, as illustrated in FIG. 21, after removing the protective film 103 of the trench STA, the insulating layer 110A is removed through the trench STA. This process is performed by, for example, a method, such as wet etching or dry etching. As illustrated in FIG. 21, since the inter-block insulating layer ST1 is provided between the first memory block BLK1 and the second memory block BLK2, liquid or gaseous etchant only reaches halfway along the Y-direction of the second memory block BLK2. For this reason, the insulating layers 110A remain unetched from halfway along the second memory block BLK2 to the interplanar structure IPS side.

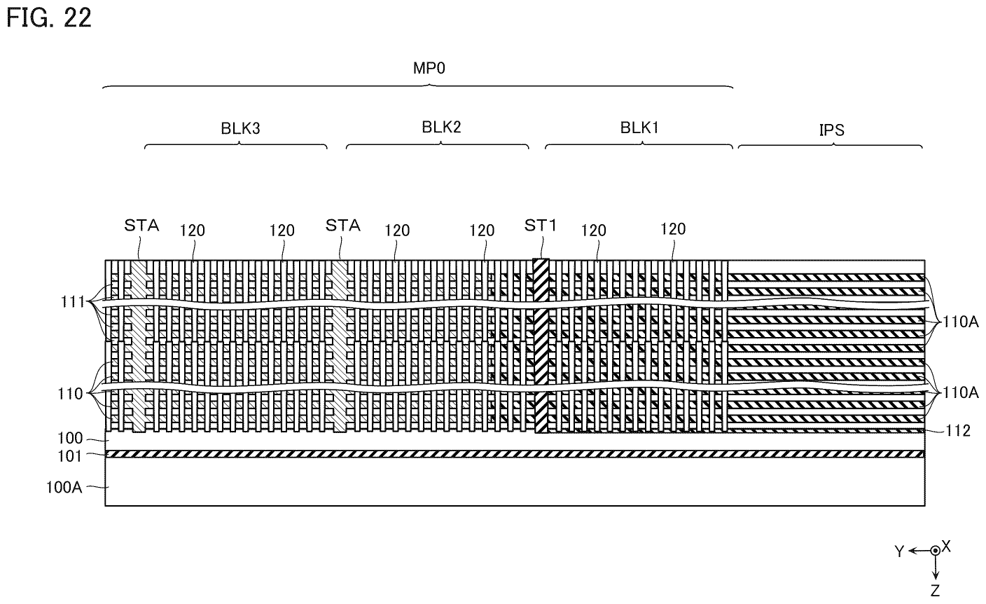

Next, as illustrated in FIG. 22, for example, the conductive layer 110 is formed in a space where the insulating layer 110A has been removed through the trench STA. The conductive layer 110 extends in the X-direction and the Y-direction and stops at a position where the insulating layer 110A of the second memory block BLK2 is present. This process is performed by a method, such as CVD, for example.

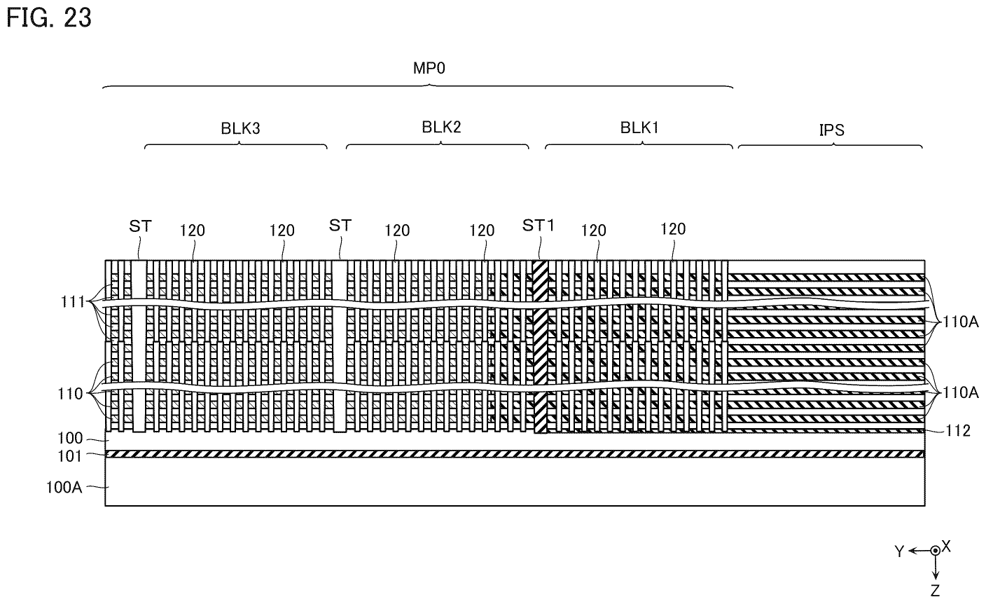

Next, for example, as illustrated in FIG. 23, the conductive layer 110 in the trench STA is removed to form the inter-block insulating layer ST. For example, this process is performed by a method, such as RIE, CVD.

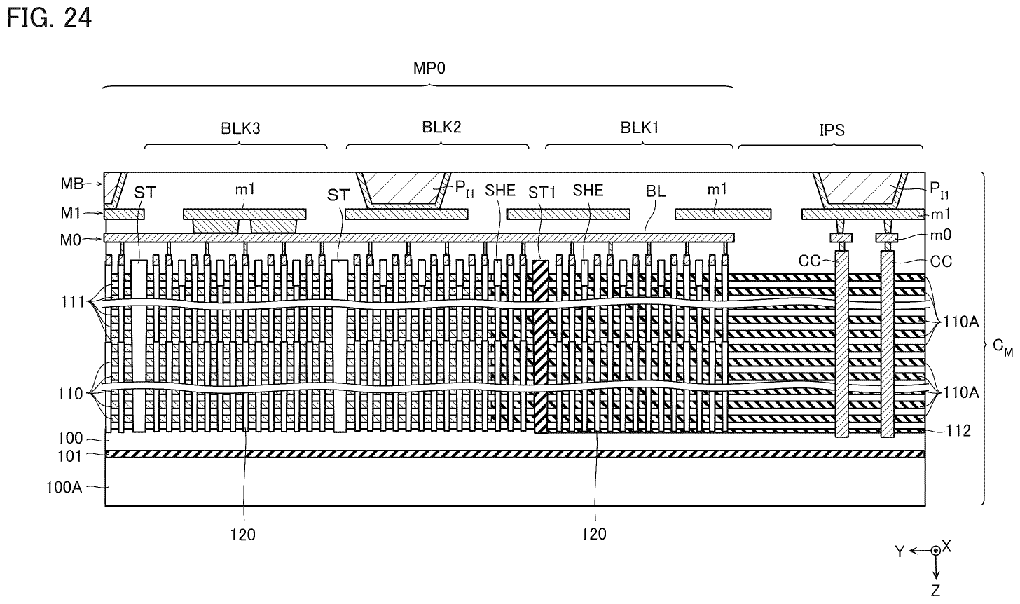

Next, as illustrated in FIG. 24, for example, the via-contact electrodes CC are formed to penetrate the interplanar structure IPS in the Z-direction. Then, the inter-string unit insulating layers SHE are formed, and subsequently the wirings m0, m1, the bit lines BL, and the first bonding electrodes P_{I1} and the like are formed in the wiring layers M0 and M1 and the chip bonding electrode layer MB. This process is performed by a method, such as CVD, photolithography, and etching.

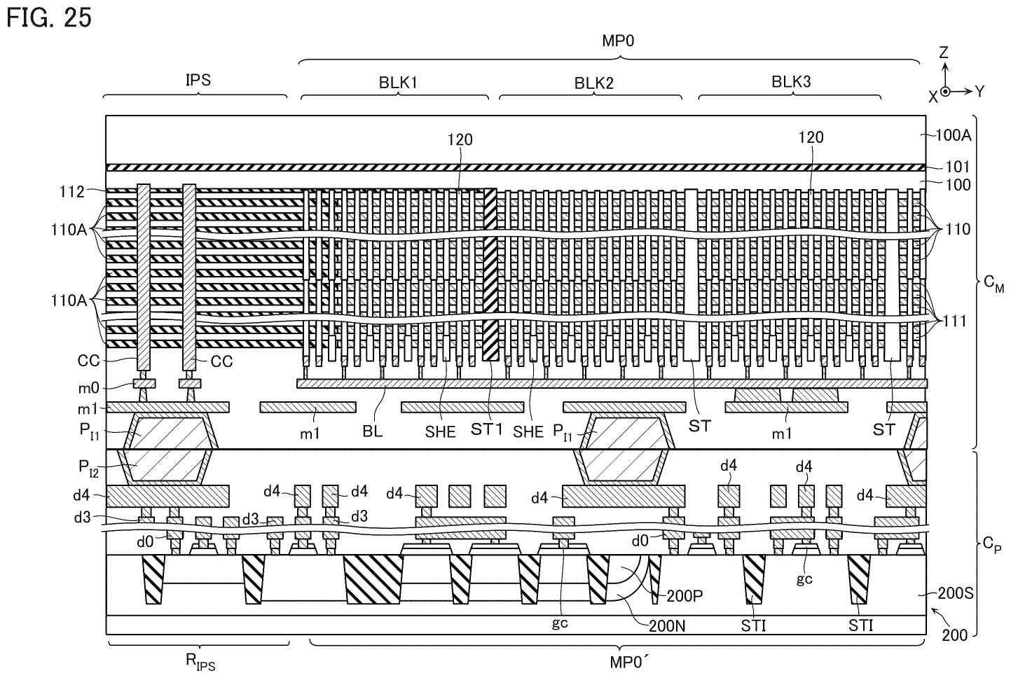

Next, for example, as illustrated in FIG. 25, the chip C_{M} and chip C_{P} are bonded together. In this bonding process, for example, a wafer of the chip C_{M} is pressed against a wafer of the chip C_{P} to make the wafer of the chip C_{M} adhere to the wafer of the chip C_{P}, and then heat treatment is performed. This bonds the chip C_{M} to the chip C_{P} via the first bonding electrode P_{I1} and the second bonding electrode P_{I2}.

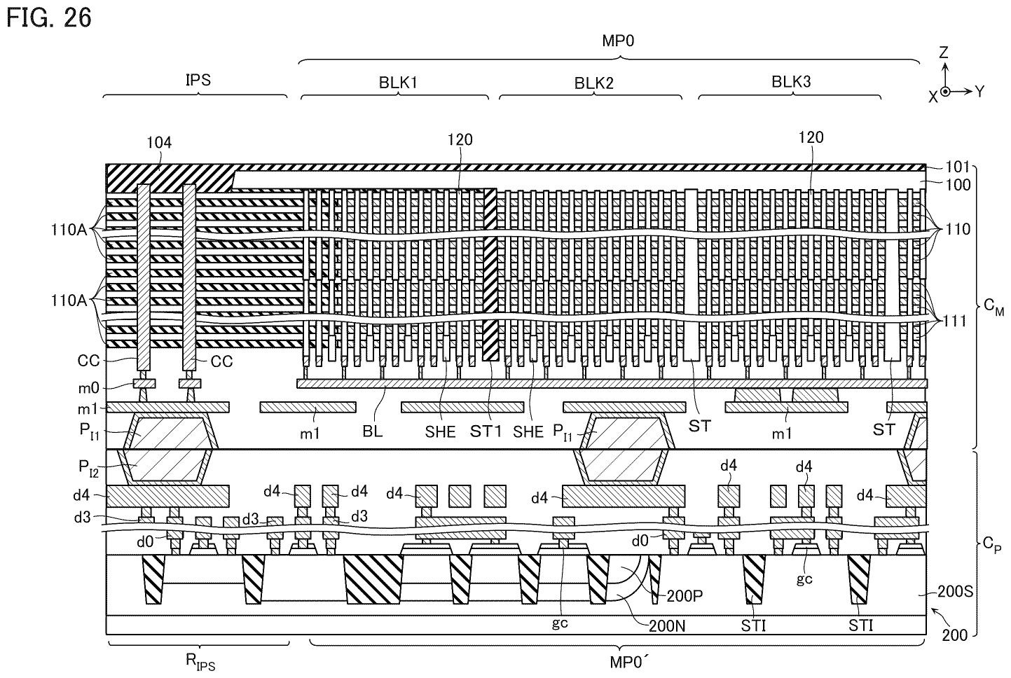

Next, as illustrated in FIG. 26, for example, the semiconductor substrate 100A on the chip C_{M} side is removed down to the insulating layer 101, and an insulating layer 104 is formed that divides the conductive layers 100 in the Y-direction in a part of the interplanar structure IPS. This process is performed by a processes, such as CMP, etching, and CVD, for example.

Subsequently, the wirings ma, the external pad electrodes P_{X}, and the like are formed on the insulating layer 101 of the chip C_{M}, and the memory die MD is formed by dicing the structure in which the wafers are bonded together.

### [Effect of First Embodiment]

As a method of electrically insulating and separating between the memory planes MP adjacent to one another in the Y-direction, it is known that a dummy staircase portion is formed between the memory planes MP adjacent to one another in the Y-direction when forming the staircase portion STP of the hook-up region R_{HU} to physically separate between the memory planes MP. This method requires a space in the Y-direction to form the dummy staircase portion for each of the memory planes MP adjacent to one another in the Y-direction. As a result, it is not possible to reduce a size of the memory chip in the Y-direction.

In this respect, in the memory die MD according to the embodiment, the dummy staircase portion is not provided between the memory planes MP adjacent to one another in the Y-direction, and the interplanar structure IPS is provided. The interplanar structure IPS is a stacked structure of the insulating layers 110A before they are replaced by the conductive layers 110 in the adjacent memory block BLK and the interlayer insulating layers 111. Therefore, the adjacent memory planes MP are insulated and separated, and there is no need for the dummy staircase portion. This makes it possible to reduce the size in the Y-direction. This makes it possible to reduce a size of the entire chip.

### Second Embodiment

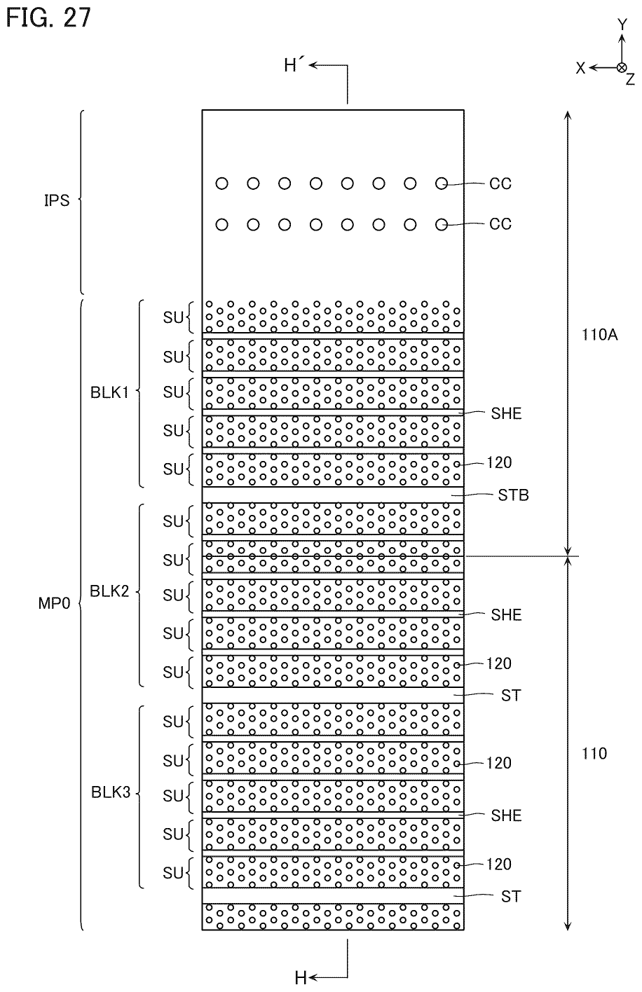

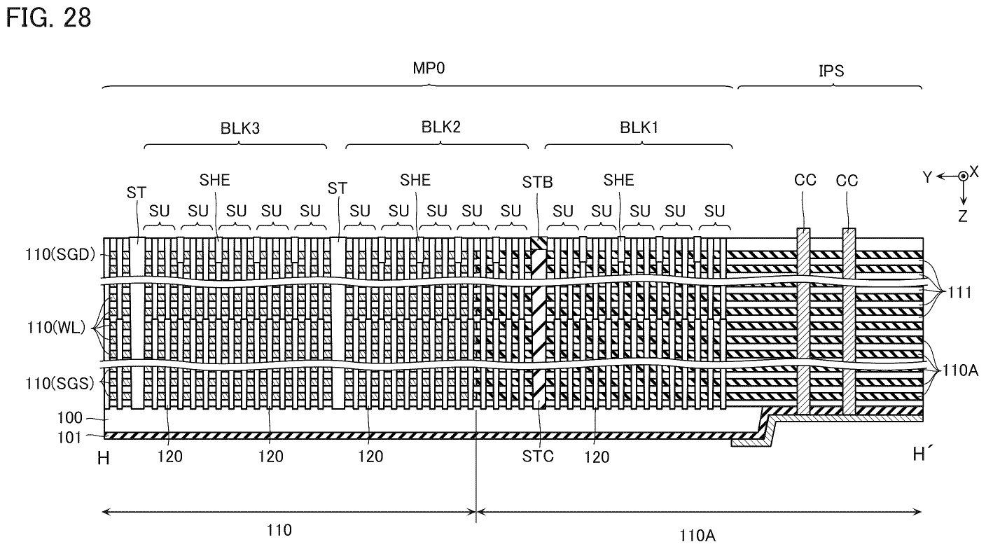

FIGS. 27 and 28 illustrate the configuration of the memory die MD according to the second embodiment. FIG. 27 is an enlarged plan view of a portion of the chip C_{M} indicated by D in FIG. 4. FIG. 28 is a cross-sectional view of a part of the base layer L_{SB} and the memory cell array layer L_{MCA} of the chip C_{M}, cut along the H-H′ line in FIG. 27, and viewed in the direction of the arrow.

In the embodiment, an inter-block insulating layer STB and an inter-block insulating layer STC are provided between the first memory block BLK1 and the second memory block BLK2. The inter-block insulating layer STB extends in the X-direction. The inter-block insulating layer STC extends in the X-direction and the Z-direction. The inter-block insulating layer STB and the inter-block insulating layer STC are stacked in the Z-direction, with the inter-block insulating layer STC on a side of the conductive layer 100 and the inter-block insulating layer STB on a side opposite to the conductive layer 100. The inter-block insulating layer STB may, for example, contain silicon oxide (SiO₂) or the like. The inter-block insulating layer STC may, for example, contain amorphous silicon (a-Si) or the like. Other configurations are the same as the first embodiment.

### [Manufacturing Method of Memory Die MD]

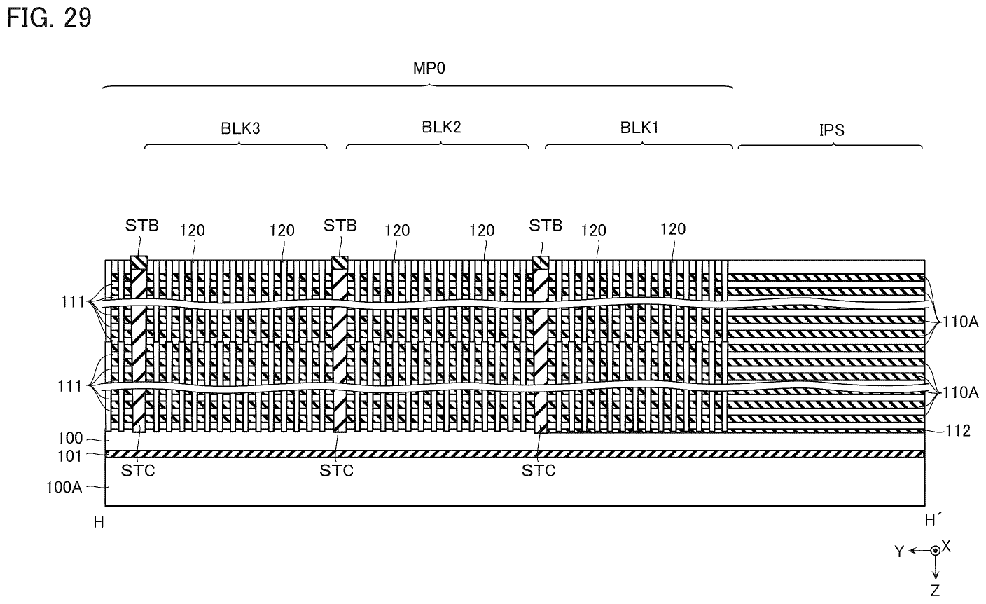

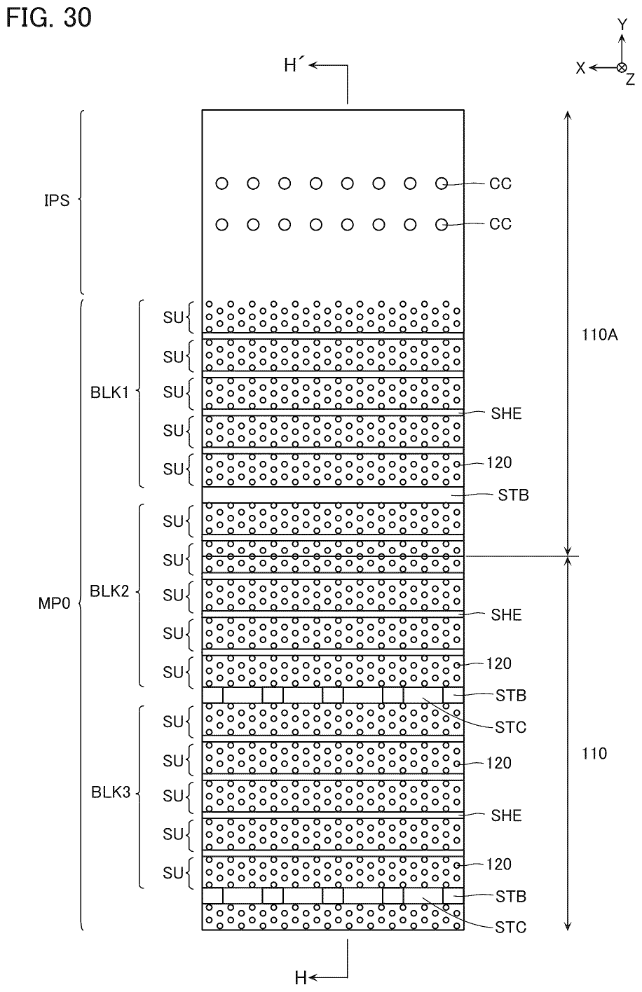

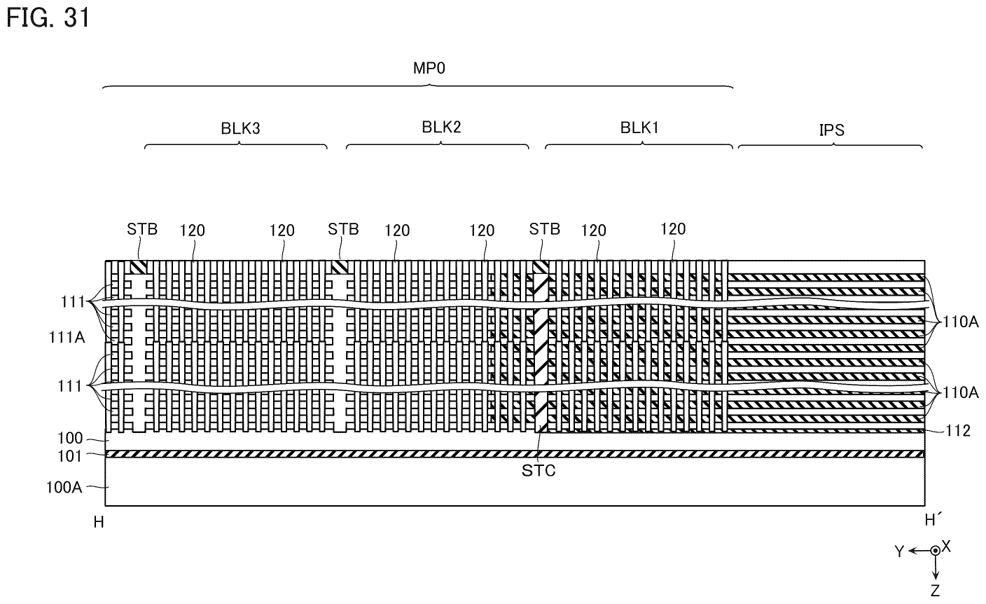

Next, referring to FIGS. 29 to 31, the manufacturing method of the memory die MD of the second embodiment is described. FIG. 29 is a cross-sectional view for describing the method of manufacturing the chip C_{M} corresponding to FIG. 28. FIG. 30 is a plan view for describing the method of manufacturing the chip C_{M} corresponding to FIG. 27. FIG. 31 is a cross-sectional view for describing the method of manufacturing the chip C_{M} corresponding to FIG. 28.

The manufacturing process up to a point illustrated in FIG. 17 is the same as the first embodiment. For the structure in the state illustrated in FIG. 17, the inter-block insulating layers STB and STC are formed between the memory blocks BLK, as illustrated in FIG. 29. For example, this process is performed by a method, such as RIE and CVD.

Next, as illustrated in FIG. 30, a selective etching divides the inter-block insulating layers STB excluding the inter-block insulating layer STB between the first memory block BLK1 and the second memory block BLK2 in the X-direction to expose the inter-block insulating layer STC thereunder. This process is performed by a method, such as RIE, for example.

Next, as illustrated in FIG. 31, the inter-block insulating layers STC exposed between the inter-block insulating layers STB is removed, and then the insulating layers 110A are removed. For example, this process is performed by a method, such as wet etching or dry etching. At this time, as illustrated in FIG. 31, the inter-block insulating layers STB function as bridges to prevent distortion of the stacked body.

However, since the inter-block insulating layer STB is not divided in the X-direction between the first memory block BLK1 and the second memory block BLK2, the inter-block insulating layer STC remains. For this reason, the liquid or gaseous etchant only reaches halfway along the Y-direction of the second memory block BLK2. For this reason, the insulating layer 110A remains on the interplanar structure IPS side from halfway along the second memory block BLK2.

Since the subsequent processes are almost the same as those illustrated in FIG. 22 and later, the detailed explanation is omitted. In addition, the inter-block insulating layer STB divided in the X-direction other than the inter-block insulating layer STB between the first memory block BLK1 and the second memory block BLK2 may be removed or may remain in the subsequent processes.

### [Effect of Second Embodiment]

In this embodiment, the following effects are achieved in addition to the same effects as the first embodiment. That is, when replacing the insulating layers 110A with the conductive layers 110, only the inter-block insulating layer STB at a boundary portion of the memory planes MP is not divided in the X-direction, among the inter-block insulating layers STB that function as the bridges to prevent distortion of the stacked structure. As a result, the same effect as the first embodiment can be achieved without making too many changes to the manufacturing process that uses the bridges.

### Third Embodiment

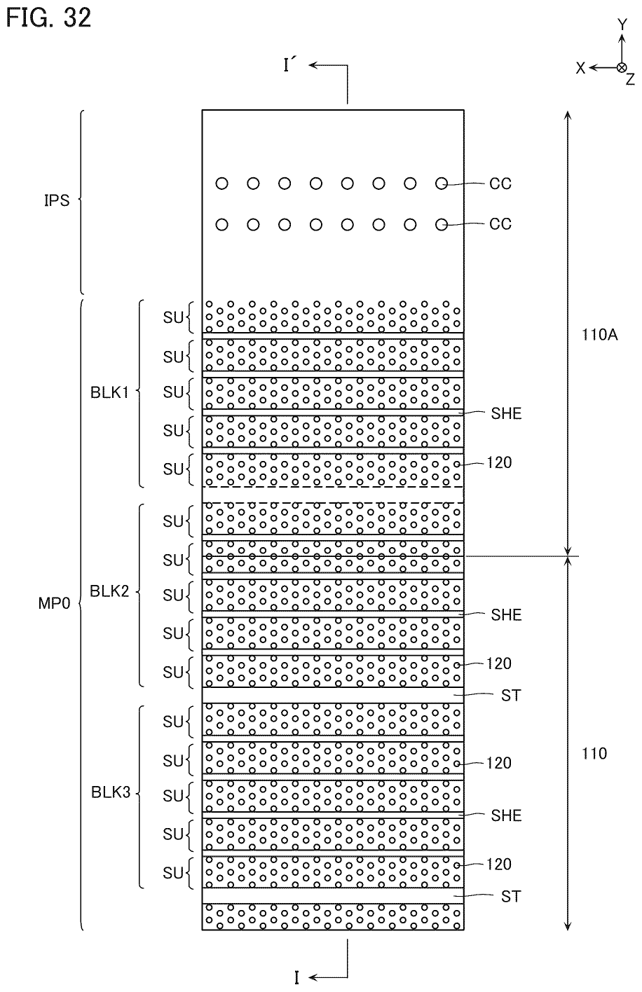

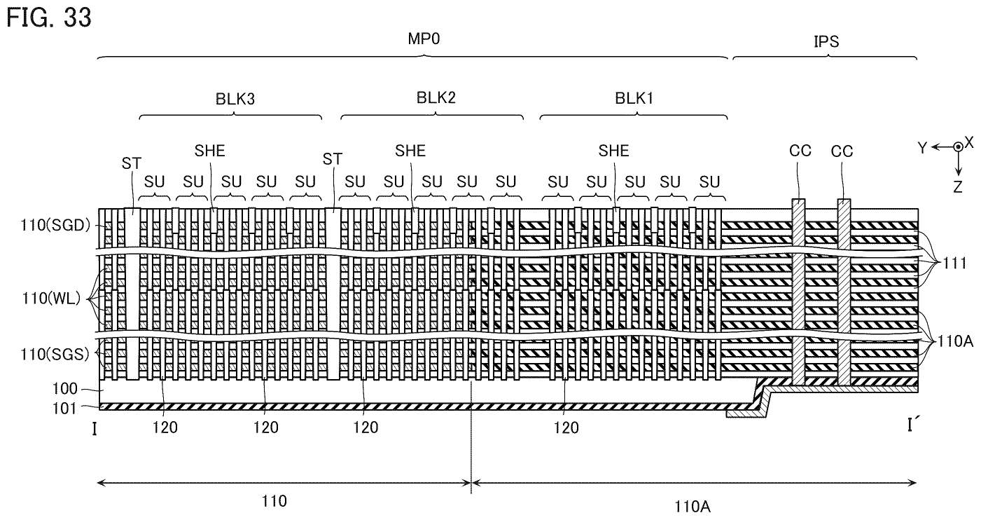

FIGS. 32 and 33 illustrate configurations of the memory die MD according to the third embodiment. FIG. 32 is an enlarged plan view of a part indicated by D of the chip C_{M} illustrated in FIG. 4. FIG. 33 is a cross-sectional view of a part of the Base Layer L_{SB} and the memory cell array layer L_{MCA} of the chip C_{M}, cut along the H-H′ line in FIG. 27, and viewed in the direction of the arrow.

In this embodiment, the inter-block insulating layer is not provided between the first memory block BLK1 and the second memory block BLK2. Other configurations are the same as the first embodiment.

Also in this embodiment, it is considered that the liquid or gaseous etchant from the inter-block insulating layer ST between the second memory block BLK2 and the third memory block BLK3 does not reach a position between the first memory block BLK1 and the second memory block BLK2. Thus, a stacked structure is formed with the insulating layers 110A and the interlayer insulating layers 111 in the interplanar structure IPS. As a result, the same effect as the first embodiment can be achieved. According to the embodiment, since the process merely omits the formation of the inter-block insulating layer ST to be formed at an outermost end in the Y-direction of the memory plane MP, there is almost no need to change the existing manufacturing process.

### OTHER EMBODIMENTS

The semiconductor memory devices according to the first embodiment to the third embodiment have been described above. However, the above-described configurations are merely examples, and the specific configurations are adjustable as appropriate.

For example, in the respective above-described embodiments, the hook-up region R_{HU} is provided in the center portion of the memory plane. However, the hook-up region R_{HU} may be provided at one end or both ends in the X-direction of the memory plane MP.

In the above-described embodiments, the example of application to the NAND flash memory has been described. However, the technique described in this specification is also applicable to a configuration other than the NAND flash memory, for example, a three-dimensional NOR flash memory. Additionally, the technique described in this specification is also applicable to semiconductor memory devices other than the flash memory, for example, a three-dimensional DRAM.

### [Others]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate; and
a memory cell array layer disposed apart from the semiconductor substrate in a first direction intersecting with a surface of the semiconductor substrate, wherein
the memory cell array layer includes:
a first stacked structure and a second stacked structure arranged in a second direction intersecting with the first direction; and
a third stacked structure provided between the first stacked structure and the second stacked structure,
each of the first stacked structure, the second stacked structure, and the third stacked structure includes a plurality of first layers and a plurality of first insulating layers alternately stacked in the first direction and extending in a third direction intersecting with the first direction and the second direction,
each of the first stacked structure and the second stacked structure includes a plurality of blocks arranged in the second direction,
each of the plurality of blocks includes a first semiconductor layer extending in the first direction and opposed to the plurality of first layers,
among the plurality of blocks, a plurality of blocks excluding a first block closest to the third stacked structure includes a first conductive layer in the first layer, and
the third stacked structure and the first block include a second insulating layer as the first layer.

2. The semiconductor memory device according to claim 1, wherein
among the plurality of blocks, a second block second closest to the third stacked structure includes the first conductive layer on a far side from the third stacked structure of the first layer and includes the second insulating layer on a near side from the third stacked structure of the first layer.

3. The semiconductor memory device according to claim 1, wherein
each of the first stacked structure and the second stacked structure includes a plurality of third insulating layers extending in the first direction and the third direction between a plurality of blocks excluding the first block among the plurality of blocks.

4. The semiconductor memory device according to claim 3, wherein:
each of the first stacked structure and the second stacked structure includes a fourth insulating layer extending in the first direction and the third direction between the first block and a second block second closest to the second stacked structure.

5. The semiconductor memory device according to claim 3, wherein
each of the first stacked structure and the second stacked structure includes:
a fifth insulating layer extending in the first direction and the third direction between the first block and a second block among the plurality of blocks, the second block being second closest to the third stacked structure; and
a sixth insulating layer extending in the third direction and disposed at one end in the first direction of the fifth insulating layer.

6. The semiconductor memory device according to claim 1, wherein
each of the first stacked structure and the second stacked structure includes a hook-up region in which a staircase portion constituted of the plurality of first conductive layers is formed, in a center portion in the third direction.

7. The semiconductor memory device according to claim 1, wherein
the third stacked structure includes a via-contact electrode extending in the first direction.

8. The semiconductor memory device according to claim 1, further comprising
a second conductive layer disposed on one side in the first direction of the first stacked structure; and
a third conductive layer disposed on one side in the first direction of the second stacked structure.

9. The semiconductor memory device according to claim 8, further comprising
a seventh insulating layer disposed on one side in the first direction of the third stacked structure, wherein
the second conductive layer and the third conductive layer are electrically separated in the second direction by the seventh insulating layer.

10. The semiconductor memory device according to claim 1, wherein
the first insulating layer contains silicon oxide, and
the second insulating layer contains silicon nitride.

11. A semiconductor memory device comprising:
a semiconductor substrate; and
a memory cell array layer disposed at one side of the semiconductor substrate in a first direction intersecting with a surface of the semiconductor substrate, wherein
the memory cell array layer includes a first stacked structure and a second stacked structure arranged in a second direction intersecting with the first direction, and a third stacked structure disposed between the first stacked structure and the second stacked structure,
the memory cell array layer includes a plurality of first layers and a plurality of first insulating layers stacked alternately in the first direction throughout the first stacked structure, the third stacked structure, and the second stacked structure,
the first stacked structure includes a first block, a second block, and a third block arranged in the second direction from a side close to the third stacked structure to a side far from the third stacked structure,
in the first block, the first layer is formed by a second insulating layer, and
in the third block, the first layer is formed by a first conductive layer.

12. The semiconductor memory device according to claim 11, wherein
in the second block, the first layer on a side of the first block is formed by the second insulating layer, and the first layer on a side of the third block is formed by the first conductive layer.

13. The semiconductor memory device according to claim 11, further comprising
a third insulating layer extending in the first direction and the third direction disposed between the second block and the third block.

14. The semiconductor memory device according to claim 11, further comprising
a fourth insulating layer extending in the first direction and the third direction disposed between the first block and the second block.

15. The semiconductor memory device according to claim 11, further comprising
a fifth insulating layer extending in the first direction and the third direction and a sixth insulating layer extending in the third direction and disposed on one end in the first direction of the fifth insulating layer, between the first block and the second block.

16. The semiconductor memory device according to claim 11, wherein
the first stacked structure includes a hook-up region in which a staircase portion constituted of a plurality of first conductive layers is formed, in a center portion in the third direction.

17. The semiconductor memory device according to claim 11, wherein
the third stacked structure includes a via-contact electrode extending in the first direction.

18. The semiconductor memory device according to claim 11, further comprising:
a second conductive layer disposed on one side in the first direction of the first stacked structure; and
a third conductive layer disposed on one side in the first direction of the second stacked structure.

19. The semiconductor memory device according to claim 18, further comprising
a seventh insulating layer disposed on one side in the first direction of the third stacked structure, wherein
the second conductive layer and the third conductive layer are electrically separated in the second direction by the seventh insulating layer.

20. The semiconductor memory device according to claim 11, wherein
the first insulating layer contains silicon oxide, and
the second insulating layer contains silicon nitride.
